(19) United States
(12) Patent Application Publication
(10) Pub. No.: US 2025/0311458 A1
(43) Pub. Date: Oct. 2, 2025

(54) PHOTOELECTRIC CONVERSION APPARATUS, PHOTOELECTRIC CONVERSION SYSTEM, MOVING BODY, EQUIPMENT, AND METHOD FOR MANUFACTURING THE PHOTOELECTRIC CONVERSION APPARATUS

(71) Applicant: CANON KABUSHIKI KAISHA, Tokyo (JP)

(72) Inventors: KOSEI UEHIRA, Tokyo (JP); ALICE MORIMOTO, Kanagawa (JP); YOSHIKI KATO, Kanagawa (JP); SHINGO KITAMURA, Kanagawa (JP); TAKASHI USUI, Kanagawa (JP); HIROSHI SEKINE, Kanagawa (JP); KAZUHIRO MORIMOTO, Kanagawa (JP)

(21) Appl. No.: 19/091,662

(22) Filed: Mar. 26, 2025

(30) Foreign Application Priority Data
Mar. 29, 2024 (JP) 2024-057460

(51) Int. Cl. H10F 39/00; H10F 39/18

(52) U.S. Cl. CPC H10F 39/805; H10F 39/014; H10F 39/024; H10F 39/182; H10F 39/8057; H10F 39/807

(57) ABSTRACT

A photoelectric conversion apparatus including an uneven portion that has a groove of a semiconductor layer and that is disposed so as to correspond to a first photoelectric conversion element, an isolation portion that has a groove of the semiconductor layer and that is disposed between the first photoelectric conversion element and a second photoelectric conversion element, a first film disposed in at least part of the groove of the uneven portion, and a second film disposed in at least part of the groove of the isolation portion. The groove of the isolation portion extends through the first film into the semiconductor layer. The second film extends from a side surface of the groove of the isolation portion on the first film.

### BACKGROUND

### Technical Field

The present disclosure relates to a photoelectric conversion apparatus, a photoelectric conversion system, a moving body, equipment, and a method for manufacturing the photoelectric conversion apparatus.

### Description of the Related Art

A known photoelectric conversion apparatus can detect very weak light of a single photon level by utilizing the avalanche multiplication. Japanese Patent Laid-Open No. 2022-075774 discloses a photoelectric conversion apparatus in which an uneven structure is provided in a light receiving surface of a photoelectric conversion element and an isolation structure is provided between pixels.

Japanese Patent Laid-Open No. 2022-075774 does not include a close study on crosstalk between adjacent pixels due to refraction, diffraction, and the like occurring in the isolation structure and the uneven structure.

### SUMMARY

Accordingly, in one aspect of the present disclosure, a more suitable isolation structure or a method for manufacturing the isolation structure is provided.

In one aspect of the present disclosure, a photoelectric conversion apparatus includes a semiconductor layer having a first surface and a second surface facing the first surface, a first photoelectric conversion element disposed in the semiconductor layer, a second photoelectric conversion element disposed in the semiconductor layer, an uneven portion which is disposed in the second surface of the semiconductor layer so as to correspond to the first photoelectric conversion element and which has a groove of the semiconductor layer, an isolation portion which is disposed between the first photoelectric conversion element and the second photoelectric conversion element and which has a groove of the semiconductor layer, a first film disposed in at least part of the groove of the uneven portion on a second surface side, and a second film disposed in at least part of the groove of the isolation portion. In the photoelectric conversion apparatus, the groove of the isolation portion extends through the first film into the semiconductor layer, and the second film extends from a side surface of the groove of the isolation portion on the first film.

In another aspect of the present disclosure, a method for manufacturing a photoelectric conversion apparatus includes the steps of preparing a semiconductor layer which has a first surface and a second surface facing the first surface and in which a first photoelectric conversion element and a second photoelectric conversion element are disposed, forming a first groove by etching at a first position corresponding to a second position, at which the first photoelectric conversion element of the semiconductor layer is disposed, on a second surface side of the semiconductor layer, forming a first film in the first groove, forming a second groove by etching at a third position corresponding to a fourth position on the second surface side of the semiconductor layer between the first photoelectric conversion element and the second photoelectric conversion element of the semiconductor layer, and forming an opening in the first film in the forming of the second groove, and forming a second film so as to extend from a side surface of the second groove to cover an upper side of the first film.

Further features of the present disclosure will become apparent from the following description of exemplary embodiments with reference to the attached drawings.

### BRIEF DESCRIPTION OF THE DRAWINGS

FIG. 1 is a schematic diagram of a photoelectric conversion apparatus according to embodiments.

FIG. 2 is a schematic diagram of a pixel substrate of the photoelectric conversion apparatus according to the embodiments.

FIG. 3 is a schematic diagram of a circuit substrate of the photoelectric conversion apparatus according to the embodiments.

FIG. 4 is an example of the configuration of a pixel circuit of the photoelectric conversion apparatus according to the embodiments.

FIGS. 5A and 5B are schematic diagrams illustrating driving of the pixel circuit of the photoelectric conversion apparatus according to the embodiments.

FIGS. 6A and 6B are schematic diagrams of the section and a plane of pixels of the photoelectric conversion apparatus according to a first embodiments.

FIGS. 7A to 7H are schematic sectional views illustrating a method for manufacturing the photoelectric conversion apparatus according to the first embodiment.

FIGS. 8A to 8F are schematic sectional views illustrating the method for manufacturing the photoelectric conversion apparatus according to the first embodiment.

FIGS. 9A to 9C are schematic sectional views illustrating the method for manufacturing the photoelectric conversion apparatus according to the first embodiment.

FIGS. 10A to 10G are schematic sectional views illustrating a method for manufacturing a photoelectric conversion apparatus according to a second embodiment.

FIGS. 11A to 11C are schematic sectional views illustrating a photoelectric conversion apparatus according to a third embodiment.

FIGS. 12A and 12B are schematic sectional views illustrating a photoelectric conversion apparatus according to a fourth embodiment.

FIG. 13 is a schematic sectional view illustrating a photoelectric conversion apparatus according to a fifth embodiment.

FIG. 14 is a schematic sectional view illustrating a photoelectric conversion apparatus according to a sixth embodiment.

FIGS. 15A to 15D are schematic sectional views illustrating a method for manufacturing the photoelectric conversion apparatus according to the sixth embodiment.

FIGS. 16A to 16D are schematic sectional views illustrating the method for manufacturing the photoelectric conversion apparatus according to the sixth embodiment.

FIGS. 17A and 17B are schematic sectional views illustrating a photoelectric conversion apparatus according to a seventh embodiment.

FIGS. 18A and 18D are schematic sectional views illustrating the photoelectric conversion apparatus according to the seventh embodiment.

FIGS. 19A to 19C are schematic diagrams illustrating equipment, a photoelectric conversion system, and a moving body according to an eighth embodiment.

FIG. 20 is a schematic diagram illustrating a photoelectric conversion system according to a ninth embodiment.

FIGS. 21A and 21B are schematic diagrams illustrating a photoelectric conversion system according to a tenth embodiment.

FIGS. 22A and 22B are schematic diagrams illustrating a photoelectric conversion system according to an eleventh embodiment.

FIG. 23 is a schematic diagram illustrating a medical system according to a twelfth embodiment.

### DESCRIPTION OF THE EMBODIMENTS

The following embodiments are intended to embody the technical gist of the present disclosure but not to limit the invention. The sizes and the positional relationships of members illustrated in the drawings may be exaggerated for the sake of clarity of the illustration. In the following description, the same elements may be denoted by the same reference numerals, thereby to omit description thereof.

Hereinafter, the embodiments of the present disclosure are described in detail with reference to the drawings. In the following description, terms indicating specific directions and positions (for example, “above”, “below”, “right”, “left”, and other terms including these terms) are used according to need. Use of these terms is intended to increase ease of understanding of the embodiments with reference to the drawings. It is not intended that the meaning of these terms limit the technical scope of the invention.

Herein, the term “plan view” refers to looking in a direction perpendicular to a light incident surface of a semiconductor layer. The term “sectional view” refers to a plane in a direction perpendicular to the light incident surface of the semiconductor layer. When the microscopically seen light incident surface of the semiconductor layer is a rough surface, the plan view is defined with reference to a macroscopically seen light incident surface of the semiconductor layer.

The semiconductor layer has a first surface and a second surface. The second surface is on the opposite side from the first surface and upon which the light is incident.

Herein, a depth direction extends from the first surface toward the second surface of the semiconductor layer where a photoelectric conversion element is disposed. Hereinafter, the “first surface” may be referred to as a “front surface” and the “second surface” may be referred to as a “rear surface”. The term “depth” of a certain point or region in the semiconductor layer means the distance from the first surface (front surface) to the point or region. It is assumed that the distance (depth) of a point (or region) Z1 from the first surface is d1 and the distance (depth) of a point (or region) Z2 from the first surface is d2. When d1>d2, this relationship may be expressed as “Z1 is deeper than Z2” or “Z2 is shallower than Z1”. When the distance (depth) of a point (region) Z3 from the first surface is d3 and the relationships d1>d3>d2 hold, the relationships may be expressed as “Z3 is disposed at a depth between Z1 and Z2” or “Z3 is disposed between Z1 and Z2 in the depth direction”.

In the following description, an anode of an avalanche photodiode (APD) serving as the photoelectric conversion element is a fixed potential, and a signal is fetched from the cathode side. Accordingly, a semiconductor region of a first conductivity type in which electric charges of the same polarity as the polarity of signal electric charges are a majority carrier is an N-type semiconductor region, and a semiconductor region of a second conductivity type in which the electric charges of a different polarity from the polarity of the signal electric charges are a majority carrier is a P-type semiconductor region. The present disclosure also holds when the cathode of the APD is the fixed potential, and the signal is fetched from the anode side. In this case, a semiconductor region of the first conductivity type in which the electric charges of the same polarity as the polarity of the signal electric charges are the majority carrier is the P-type semiconductor region, and a semiconductor region of the second conductivity type in which the electric charges of a different polarity from the polarity of the signal electric charges are the majority carrier is the N-type semiconductor region. In the following description, one of the nodes of the APD is the fixed potential. However, the potentials of both the nodes may vary.

Herein, when the term “impurity concentration” is simply used, this means a net impurity concentration acquired by subtracting an amount compensated by the impurities of an opposite conductivity type. That is, the “impurity concentration” refers to a net doping concentration. A region in which an added impurity concentration of the P type is higher than the added impurity concentration of the N type is a P-type semiconductor region. In contrast, a region in which an added impurity concentration of the N type is higher than the added impurity concentration of the P type is an N-type semiconductor region.

In the following embodiments, mutual connection of elements of a circuit may be described. In this case, even when a different element is interposed between the elements of interest, the elements of interest are treated as being connected unless otherwise stated. It is assumed that, for example, an element A is connected to one of nodes of a capacitor element C having a plurality of nodes and an element B is connected to the other node of the capacitor element C. Even in such a case, the element A and the element B are treated as being connected unless otherwise stated. When the elements are connected to each other without another element interposed therebetween, this may be expressed as “directly connected”. When no other element is provided between the element A and the capacitor element C in the above-described example, it can be said that the element A and the capacitor element C are directly connected to each other.

Regarding metal members such as wiring and pads described herein, each type of the metal members may only include metal of a single element or may include a mixture (alloy). For example, wiring described as copper wiring may only include copper or mainly include copper and further include another element than copper. For example, pads to be connected to external terminals may only include aluminum or mainly include aluminum and further include another element (for example, copper) than aluminum. The copper wiring and the aluminum pads described herein are merely exemplary and the types of metal may be changed to various other types of metal.

The wiring and the pads described herein are examples of the metal members used in a semiconductor apparatus (photoelectric conversion apparatus) and may also be applied to other metal members.

According to each embodiment to be described below, mainly, an image capturing apparatus is described as an example of the photoelectric conversion apparatus. However, each embodiment is not limited to the image capturing apparatus and also applicable to other examples of the photoelectric conversion apparatus. For example, the embodiment may be applied to a detection apparatus configured to detect light, a distance measuring apparatus (an apparatus for, for example, measuring a distance using focus detection or time of flight (TOF)), a light measuring apparatus (an apparatus for, for example, measuring an incident light quantity), and the like.

### Description of Photoelectric Conversion Apparatus

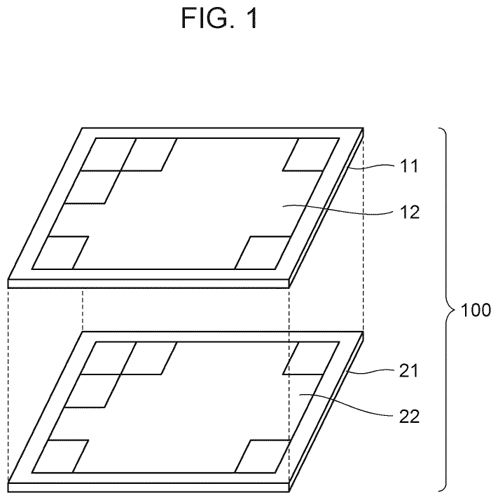

Configurations of the photoelectric conversion apparatus and a method for driving the photoelectric conversion apparatus common to the embodiments according to the present disclosure will be described with reference to FIGS. 1 to 5B.

FIG. 1 illustrates a configuration of a photoelectric conversion apparatus 100 according to the embodiments of the present disclosure. Hereinafter, in an example to be described, the photoelectric conversion apparatus 100 is a lamination-type photoelectric conversion apparatus. That is, in the example to be described, the photoelectric conversion apparatus has the configuration in which two substrates including a sensor substrate 11 and a circuit substrate 21 are laminated together and electrically connected to each other. However, the photoelectric conversion apparatus is not limited to this. For example, in a photoelectric conversion apparatus, a configuration included in the sensor substrate 11 and a configuration included in the circuit substrate, which will be described later, may be disposed in a common semiconductor layer. Hereinafter, the photoelectric conversion apparatus in which the configuration included in the sensor substrate 11 and the configuration included in the circuit substrate are disposed in the common semiconductor layer is also referred to as a non-lamination-type photoelectric conversion apparatus.

The sensor substrate 11 includes a first semiconductor layer including photoelectric conversion elements 102, which will be described later, and a first wiring structure. The circuit substrate 21 includes a second semiconductor layer including circuits such as a signal processing circuit 103 and the like, which will be described later, and a second wiring structure. The photoelectric conversion apparatus 100 is formed by laminating the second semiconductor layer, the second wiring structure, the first wiring structure, and the first semiconductor layer in this order.

FIG. 1 illustrates the photoelectric conversion apparatus of a rear surface irradiation-type in which the light enters through the first surface and the circuit substrate is disposed on the second surface on the opposite side from the first side. In the case of the non-lamination-type photoelectric conversion apparatus, a surface on the side where transistors of the signal processing circuit are disposed is referred to as the second surface. In the case of the rear surface irradiation-type photoelectric conversion apparatus, the first surface opposite from the second surface of the semiconductor layer serves as the light incident surface. In the case of a front surface irradiation-type photoelectric conversion apparatus, the second surface of the semiconductor layer serves as the light incident surface.

Although the sensor substrate 11 and the circuit substrate 21 are diced chips in the description below, the sensor substrate 11 or the circuit substrate 21 is not limited to a chip. For example, each substrate may be a wafer. The substrates in the form of a wafer may be laminated together and then diced. Alternatively, the substrates separated into chips may be laminated and joined together.

A pixel region 12 is disposed in the sensor substrate 11. A circuit region 22 configured to process signals detected in the pixel region 12 is disposed in the circuit substrate 21.

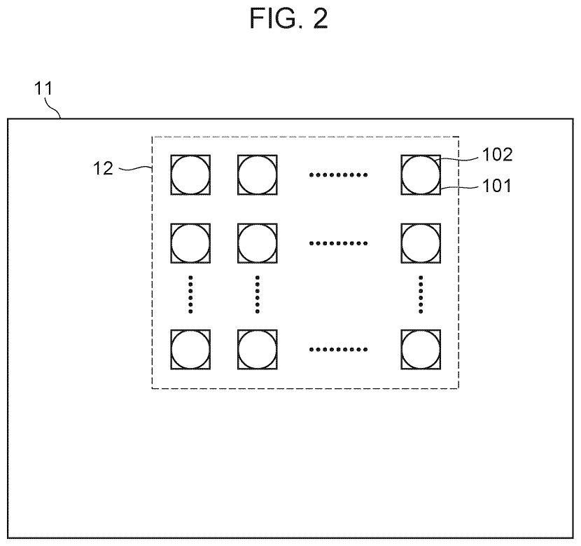

FIG. 2 illustrates arrangement in the sensor substrate 11. Pixels 101 including photoelectric conversion elements 102 including the APDs are arranged in a two-dimensional manner. Thus, the pixel region 12 is formed.

Although the pixels 101 are typically used for forming images, the pixels 101 do not necessarily form images when used in the TOF. That is, the pixels 101 may be pixels that measure the amount of light and time at which the light arrives.

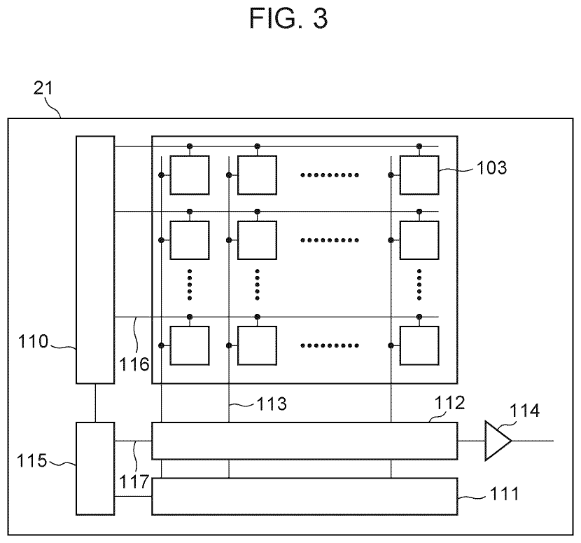

FIG. 3 illustrates the configuration of the circuit substrate 21. The circuit substrate 21 includes signal processing circuits 103 configured to process the electric charges having undergone photoelectric conversion by the photoelectric conversion elements 102 illustrated in FIG. 2, a reading circuit 112, a control pulse generation unit 115, a horizontal scanning circuit unit 111, signal lines 113, and a vertical scanning circuit unit 110.

The photoelectric conversion elements 102 illustrated in FIG. 2 and the signal processing circuits 103 illustrated in FIG. 3 are electrically connected to each other via connection wiring provided on a pixel-by-pixel bases.

The vertical scanning circuit unit 110 receives control pulses supplied from the control pulse generation unit 115 and supplies the control pulses to the pixels. A logic circuit such as shift register or an address decoder is used for the vertical scanning circuit unit 110.

The control pulse generation unit 115 includes a signal generation unit 215 configured to generate control signals P_CLK for a switch, which will be described later. As will be described later, the signal generation unit 215 generates pulse signals that control a switch. For example, the signal generation unit 215 may generate a control signal P_CLK common to a plurality of pixels in the pixel region. Alternatively, the signal generation unit 215 may generate a control signal P_CLK for each of the pixels. When the common pulse signal P_CLK is generated, at least one of the following items is caused to correspond to an exposure period: a signal P_EXP controlling an exposure period; a period of the pulse signal; the number of pulses; and a pulse width.

Furthermore, when the control signal P_CLK is controlled pixel-by-pixel, the signal can be generated by using both an input signal P_CLK_IN output from the control pulse generation unit 115 and the signal P_EXP controlling the exposure period. The control pulse generation unit 115 can include, for example, a frequency dividing circuit. Thus, the control can be simplified, and an increase in the number of elements can be suppressed.

The signals output from the photoelectric conversion elements 102 of the pixels are to be processed by the signal processing circuits 103. A counter, memory, and the like are provided in a signal processing circuit 103, and the memory holds digital values.

The horizontal scanning circuit unit 111 inputs to the signal processing circuits 103 control pulses that select columns one after another so as to read the signals from the memory of pixels holding the digital signals.

For the selected column, the signals are output from the signal processing circuits 103 of the pixels selected by the vertical scanning circuit unit 110 to the signal line 113.

The signals output to the signal line 113 are output to a recording unit or signal processing unit outside the photoelectric conversion apparatus 100 via an output circuit 114.

Referring to FIG. 2, the pixels 100 may be arranged in a one-dimensional manner in the pixel region 12. The function of the signal processing circuit 103 is not necessarily provided in each of all the pixels 101. For example, a single signal processing circuit 103 may be shared between a plurality of pixels 101 and perform signal processing sequentially.

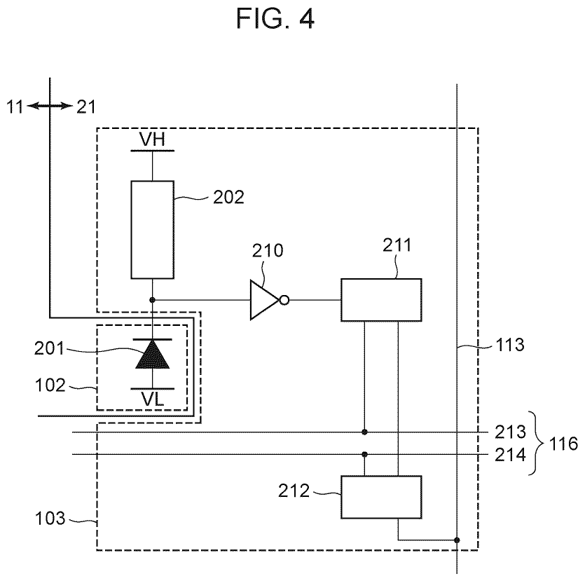

FIG. 4 is an example of a block diagram including equivalent circuits of FIGS. 2 and 3. Each photoelectric conversion element 102 including an APD 201 is provided on the sensor substrate 11 in FIG. 2 and other members are provided on the circuit substrate 21.

The APD 201 generates electric charge pairs corresponding to the incident light by using photoelectric conversion. A voltage VL (first voltage) is supplied to the anode of the APD 201. Furthermore, a voltage VH (second voltage), which is higher than the voltage VL supplied to the anode, is supplied to the cathode of the APD 201. Such reverse bias voltages with which the APD 201 performs an avalanche multiplication operation are supplied to the anode and the cathode. When a state in which such voltages are supplied is assumed, electric charges generated by the incident light cause avalanche multiplication, and an avalanche current is generated.

When reverse bias voltages are supplied, there are a Geiger mode and a linear mode. In the Geiger mode, operation is performed with a potential difference between the anode and cathode that is greater than a breakdown voltage. In the linear mode, operation is performed with a potential difference between the anode and cathode that is close to the breakdown voltage or smaller than or equal to the breakdown voltage. An APD operated in the Geiger mode is referred to as a single-photon avalanche diode (SPAD). For example, the voltage VL (first voltage) is-30 V, and the voltage VH (second voltage) is 1 V. The APD 201 may be operated in the linear mode or the Geiger mode. In the case of the SPAD, the potential difference increases compared to the APD of the linear mode, and a withstanding effect is significant.

A switch 202 is connected to a control line to which a drive voltage VH is supplied and the APD 201. The switch 202 is connected one of the nodes out of the anode and cathode of the APD. The switch 202 switches between a first potential which allows the potential difference between the anode and the cathode of the APD to cause avalanche multiplication and a second potential difference which does not allow the potential difference between the anode and the cathode of the APD to cause the avalanche multiplication. Hereinafter, switching from the second potential difference to the first potential difference is referred to as turning on of the switch 202, and switching from the first potential difference to the second potential difference is referred to as turning off of the switch 202. The switch 202 functions as a quench element. The switch 202 functions as a load circuit (quench circuit) in signal multiplication due to the avalanche multiplication so as to suppress the voltage supplied to the APD 201, thereby suppressing the avalanche multiplication (quench operation). Also, the switch 202 flows a current corresponding to the voltage drop due to the quench operation so as to return the voltage to be supplied to the APD 201 to the voltage VH (recharge operation). That is, the switch 202 functions as a control circuit that controls the occurrences of the avalanche multiplication in the APD 201.

The switch 202 can include, for example, a metal oxide semiconductor (MOS) transistor. The control signal P_CLK of the switch 202 supplied from the signal generation unit 215 is applied to a gate electrode of the MOS transistor included in the switch 202. According to the present embodiments, turning on and off of the switch 202 are controlled by controlling the voltage applied to the gate electrode of the switch 202.

The signal processing circuit 103 includes a waveform shaping unit 210, a counter circuit 211, and a selection circuit 212. Herein, it is sufficient that the signal processing circuits 103 include at least one of the waveform shaping unit 210, the counter circuit 211, and the selection circuit 212.

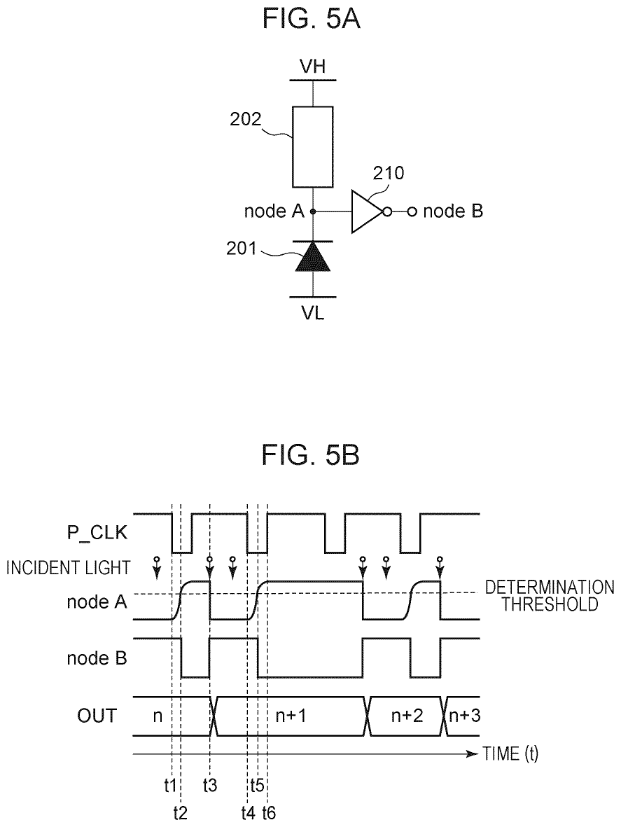

The waveform shaping unit 210 shapes changes in potential of the cathode of the APD 201 acquired in detection of a photon and outputs a pulse signal. A node of the waveform shaping unit 210 on the input side is defined as a node A, and a node of the waveform shaping unit 210 on the output side is defined as a node B. The waveform shaping unit 210 causes an output potential from the node B to change depending on whether an input potential to the node A is greater than or equal to a predetermined value or smaller than the predetermined value. For example, referring to FIG. 5B, when the input potential to the node A becomes a high potential greater than or equal to a determination threshold, the level of the output potential from the node B becomes low. When the input potential to the node A becomes lower than the determination threshold, the level of the output potential from the node B becomes high. As the waveform shaping unit 210, for example, an inverter circuit is used. In the example illustrated in FIG. 4, a single inverter is used as the waveform shaping unit 210. However, a circuit in which a plurality of inverters are connected in series may be used, or another circuit producing the waveform shaping effect may be used.

Although the quench operation and the recharge operation by using the switch 202 can be performed corresponding to the avalanche multiplication in the APD 201, electric charges generated in the APD are not necessarily determined as the output signal depending on detection timing of the photon. For example, it is assumed that the recharge operation is performed when the level of the node A becomes low due to the occurrence of the avalanche multiplication in the APD. Typically, the determination threshold of the waveform shaping unit 210 is set to a potential higher than a potential difference at which the avalanche multiplication occurs in the APD. When the photon enters the APD while, due to the recharge operation, the potential of the node A is lower than the determination threshold and is such a potential that allows the avalanche multiplication to occur in the APD, the avalanche multiplication occurs in the APD and the voltage at the node A drops. That is, since the potential of the node A reduces with a voltage lower than the determination threshold, changes in potential exceeding the determination threshold do not occur. Thus, the output potential from the node B does not change. Accordingly, despite the occurrence of the avalanche multiplication, detection of the photon is not determined as a signal. In particular, in a high-illuminance environment, photons continuously enter the APD in a short period of time. Thus, the incident light is unlikely to be determined as the signal. Consequently, despite a high illuminance, the actual number of photons having been incident are likely to be dissociated from the signals having been output.

In contrast, when the control signal P_CLK is applied to the switch 202 to switch between the on state and the off state of the switch 202, determination as the signals is possible even in the case where the photons continuously enter the APD in a short period of time. In the example described with reference to FIG. 5B, the control signal P_CLK is a pulse signal of a repeated period. In other words, in the form described with reference to FIG. 5B. the switch 202 is switched between the on state and the off state at a predetermined clock frequency. However, an effect of suppressing an increase in power consumption of the photoelectric conversion apparatus can be acquired even when a pulse signal is not a signal of a repeated period.

The counter circuit 211 counts the pulse signals output from the waveform shaping unit 210 and holds count values. Furthermore, when the control pulse pRES is supplied via a drive line 213, the signal held in the counter circuit 211 is reset.

The control pulse pSEL is supplied from the vertical scanning circuit unit 110 illustrated in FIG. 3 to the selection circuit 212 via a drive line 214 illustrated in FIG. 4 (not illustrated in FIG. 3), thereby switching electrical connection and disconnection between the counter circuit 211 and a signal line 113. The selection circuit 212 includes, for example, a buffer circuit for outputting signals or the like.

A switch such as a transistor may be disposed between the switch 202 and the APD 201 or between the photoelectric conversion element 102 and the signal processing circuit 103 so as to switch electrical connection. Likewise, supply of the voltage VH or VL to be supplied to the photoelectric conversion element 102 may be electrically switched by using a switch such as a transistor.

The configuration described according to the present embodiments uses the counter circuit 211. However, the photoelectric conversion apparatus 100 may acquire pulse detection timing by using a time to digital converter (TDC) or memory instead of the counter circuit 211. At this time, generation timing of the pulse signal output from the waveform shaping unit 210 is converted into a digital signal by using the TDC. The control pulse pREF (reference signal) is supplied from the vertical scanning circuit unit 110 illustrated in FIG. 3 to the TDC via a drive line to measure the timing of the pulse signal. The TDC acquires, as a digital signal, a value acquired when input timing of a signal output from each pixel is set as relative time with reference to the control pulse PREF.

FIG. 5B schematically illustrates the relationships among the control signal P_CLK of the switch, the potential of the node A, the potential of the node B, and the output signal. According to the present embodiments, when the level of the control signal P_CLK is high, the drive voltage VH is unlikely to be supplied to the APD, and, when the level of the control signal P_CLK is low, the drive voltage VH is supplied to the APD. The high level of the control signal P_CLK is, for example, 1 V, and the low level of the control signal P_CLK is, for example, 0 V. When the level of the control signal P_CLK is high, the switch is turned off. When the level of the control signal P_CLK is low, the switch is turned on. The resistance of the switch is higher in the case where the level of the control signal P_CLK is high than in the case where the level of the control signal P_CLK is low. In the case where the level of the control signal P_CLK is high, the recharge operation is unlikely to be performed even when the avalanche multiplication occurs in the APD. Thus, the potential supplied to the APD is lower than or equal to a breakdown voltage of the APD. Accordingly, the avalanche multiplication in the APD stops.

As illustrated in FIG. 5A, the switch 202 includes a single transistor, and the quench operation and the recharge operation can be performed with the single transistor. In this way, compared to the case where the quench operation and the recharge operation are performed by different circuit elements, the number of circuits can be reduced. In particular, in the case where each pixel includes the counter circuit, and SPAD signals are read pixel-by-pixel, the circuit area used for the switch can be reduced for the disposition of the counter circuit. Thus, an effect produced when the switch 202 includes a single transistor is significant.

At time t1, the level of the control signal P_CLK changes from high to low, the switch is turned on, and the recharge operation of the APD starts. This causes the level of the potential of the cathode of the APD to transition to high. The potential difference of the potential applied to the anode and the cathode of the APD assumes a state in which the avalanche multiplication can occur. The potential of the cathode is the same as that of the node A. Accordingly, when the level of the potential of the cathode transitions from low to high, the potential of the node A is greater than or equal to the determination threshold at time t2. At this time, the pulse signal output from the node B is reversed, and the level of this pulse signal changes from high to low. After that, the potential difference of drive voltage VH-drive voltage VL is applied to the APD 201. The level of the control signal P_CLK becomes high, and the switch is turned off.

Next, at time t3, when the photon enters the APD 201, the avalanche multiplication occurs in the APD 201, and the voltage of the cathode drops. That is, the voltage of the node A drops. When the amount of the voltage drop further increases and the voltage difference applied to the APD 201 reduces, the avalanche multiplication of the APD 201 stops as observed at the time t2, and a voltage level of node A does not drop further from a certain value. When the voltage of the node A becomes lower than the determination threshold midway during dropping of the voltage of the node A, the level of the voltage of the node B changes from low to high. That is, part of an output waveform exceeding the determination threshold at the node A is subjected to the waveform shaping performed by the waveform shaping unit 210 and output as the signal at the node B. Then, counting is performed by the counter circuit, and the count value of the counter signal output from the counter circuit increases by the number corresponding to 1 LSB.

The photon enters the APD between the time t3 and time t4. However, the switch is turned off, and the voltage applied to the APD 201 does not become a potential difference that allows the avalanche multiplication to occur. Thus, the voltage level of the node A does not exceed the determination threshold.

At the time t4, the level of the control signal P_CLK changes from high to low, and the switch is turned on. As a result, a current compensating for the amount corresponding to the voltage drop from the drive voltage VH flows through node A, and the level of the voltage of the node A transitions to an original voltage level. At this time, the voltage of the node A becomes greater than or equal to the determination threshold at time t5. Thus, the pulse signal of the node B is reversed, and the level of this pulse signal changes from high to low.

At time t6, the node A is statically determinate at the original voltage level, and the level of the control signal P_CLK changes from low to high. Accordingly, the switch is turned off. Also in the following description, as has been described in operations from the time t1 to the time t6, the potentials of the nodes and signal lines change corresponding to the control signal P_CLK and the entrance of the photon.

Hereinafter, a photoelectric conversion apparatus according to the embodiments will be described.

### First Embodiment

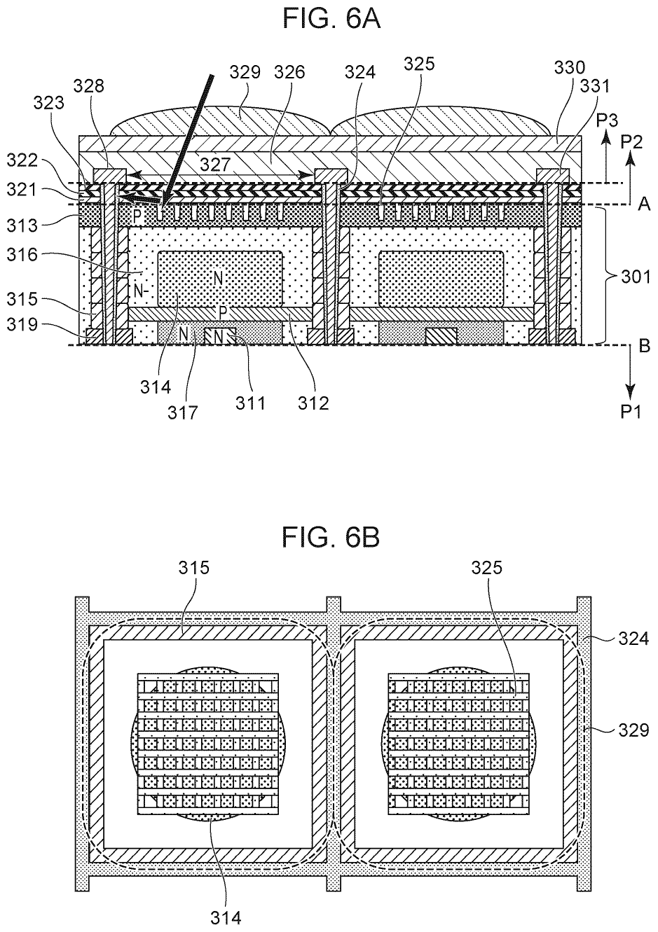

A first embodiment is described with reference to FIGS. 6A to 8F. FIGS. 6A and 6B are schematic diagrams illustrating the photoelectric conversion apparatus according to the present embodiment. FIG. 6A is a schematic sectional diagram of two pixels of the photoelectric conversion apparatus. FIG. 6B is a schematic plan view of the two pixels of the photoelectric conversion apparatus. In FIG. 6B, for ease of understanding, not all but an arbitrary elements are illustrated in projection or in the form similar to projection.

Referring to FIG. 6A, the sectional structure of the photoelectric conversion apparatus is described. The photoelectric conversion apparatus includes a semiconductor layer 301, a first film 321, a second film 322, a third film 323, isolation portions 324, uneven portions 325, a fourth film 326, a light shield 328, microlenses 329, and a color filter 330. The light shield 328 has openings 327. Another semiconductor layer where wiring structures and circuits are disposed is omitted from FIG. 6A. The semiconductor layer 301 has a first surface P1 and a second surface P2 and includes the APD including a plurality of semiconductor regions. The first film 321, the second film 322, the third film 323, the fourth film 326, the light shield 328, the microlenses 329, the color filter 330 are disposed on the second surface P2 side of the semiconductor layer 301. The light passes through the microlenses 329, the color filter 330, the openings 327 and enters the semiconductor layer 301 through the second surface P2.

The second film 322 and the fourth film 326 are disposed for desired purposes such as planarization, antireflection, and an etching stopper. The second film 322 and the fourth film 326 may be insulation films. The second film 322 may be, for example, silicon nitride or silicon oxynitride. The second film 322 may have a function of reducing reflection of the light incident upon the semiconductor layer 301 by optically adjusting the relation ships with other films such as the semiconductor layer 301, the first film 321, and the third film 323. The fourth film 326 may be silicon oxide or an organic material having a planarizing function. The color filter 330 can be replaced with any of various optical filters other than the color filter such as an infrared cut filter and a monochrome filter. Although the color filter 330 is an RGB filter, a complementary color filter, an RGBW filter including a transparent filter, or the like may be used. In addition to the color filter layer, the color filter 330 may include one or more desired layers such as a layer for planarization disposed below the color filter layer, a layer for planarizing the color filter layer disposed on the color filter layer, both of these layers, or another wavelength cut filter. Each of the microlenses 329 may be separately disposed in a corresponding one of the pixels. Alternatively, a plurality of microlenses may be included in an integrated continuous structure.

A plurality of semiconductor regions disposed in the semiconductor layer 301 are described. The following semiconductor regions are provided in the semiconductor layer 301: a first semiconductor region 311; a second semiconductor region 312; a third semiconductor region 313; a fourth semiconductor region 314; a fifth semiconductor region 315; a sixth semiconductor region 316; a seventh semiconductor region 317; an eighth semiconductor region 318; and a ninth semiconductor region 319. The first semiconductor region 311, the fourth semiconductor region 314, the sixth semiconductor region 316, and the seventh semiconductor region 317 are semiconductor regions of the first conductivity type, which is, for example, N-type semiconductor regions. The second semiconductor region 312, the third semiconductor region 313, the fifth semiconductor region 315, and the ninth semiconductor region 319 are semiconductor regions of the second conductivity type, which is, for example, P-type semiconductor regions. The APD at least includes the first semiconductor region 311 functioning as the cathode and the second semiconductor region 312 functioning as the anode. The first semiconductor region 311 and the second semiconductor region 312 are included in an avalanche multiplication region.

The first semiconductor region 311 is disposed near the first surface P1, and the second semiconductor region 312 is disposed at a position superposed on the first semiconductor region 311 in plan view. The fourth semiconductor region 314 is disposed at a position superposed on the second semiconductor region 312 in plan view, and the sixth semiconductor region 316 is disposed around the fourth semiconductor region 314. The seventh semiconductor region 317 is disposed around the first semiconductor region 311. The impurity concentration of the N type is lower in the fourth semiconductor region 314 and the seventh semiconductor region 317 than in the first semiconductor region 311. The seventh semiconductor region 317 can also function as an electric field relief region.

The size of each of the semiconductor regions is not limited to these. For example, although the size of the fourth semiconductor region 314 and the size of the seventh semiconductor region 317 are about the same, the fourth semiconductor region 314 may have a larger size than the size of the seventh semiconductor region 317 so as to collect the electric charges from wider range to the first semiconductor region 311.

Here, regarding the pixel including the APD, the size of a single pixel may be regarded as the distance from one of the isolation portions 324 to the other isolation portion 324 provided closest to the one isolation portion 324. When a size of the single pixel is L and a distance from the second surface P2 being the light incident surface to the avalanche multiplication region is d, the distance d preferably satisfies the following expression: L√2/4<d<L×√2. When the lateral size and the depth of the photoelectric conversion element satisfy this relational expression, the strength of the electric field in the depth direction and the planar direction are about the same near the first semiconductor region 311. Thus, variation in time to collect the electric charges is reduced, and accordingly, generation of timing jitter can be reduced.

Next, the uneven portions 325 are described. The uneven portions 325 are each disposed in the second surface P2 of the semiconductor layer 301. The uneven portion 325 has an uneven structure so as to cause the light incident upon the second surface P2 to, for example, scatter and diffract, so that an optical path length can vary in the semiconductor layer 301. Specifically, when the incident light diagonally travels through the semiconductor layer 301, the optical path length greater than or equal to the thickness of the semiconductor layer 301 can be ensured. Thus, compared to the case where no uneven portion 325 is provided, the wavelength of the light that can be photoelectrically converted increases. That is, the uneven portion 325 can contribute to improvement of the sensitivity on the long wavelength side. Furthermore, the uneven portion 325 causes the reflection of the incident light to reduce in the substrate. This produces an effect of improving the photoelectric conversion efficiency of the incident light. The uneven portion 325 has a groove or a recess and a film with which the groove or recess is filled. Hereinafter, for ease of the description, the groove and the recess are referred to as the groove. The uneven portion 325 can be disposed in the second surface P2 of the semiconductor layer 301 and formed by embedding the first film 321 in the groove or recess formed by removing part of the semiconductor layer 301. The first film 321 may have a lamination structure including a plurality of layers. For example, the first film 321 may include a layer functioning as a pinning film, a layer functioning as an antireflection layer, and a layer for planarization. A specific configuration will be described later.

Here, the uneven portion 325 is disposed so as to be superposed on the fourth semiconductor region 314 in plan view. In plan view, an area where the fourth semiconductor region 314 and the uneven portion 325 are superposed on each other is greater than an area of the fourth semiconductor region 314 not superposed on the uneven portion 325. With such a configuration, the electric charges generated by the incident light are likely to be collected in the avalanche multiplication region via the fourth semiconductor region 314. Furthermore, the uneven portion 325 is covered with the third semiconductor region 313. Generation of thermally excited charges in an interface of the semiconductor layer 301 of the uneven portion 325 can be reduced by the third semiconductor region 313. Thus, a dark current or a dark count rate (DCR) of the photoelectric conversion element is reduced.

The second film 322 is disposed on the first film 321 along the second surface P2. The second film 322 is positioned between the first film 321 and the third film 323. The second film 322 may be omitted. In this case, the third film 323 is disposed on the first film 321.

Each of the isolation portions 324 has an isolation structure and is disposed, for example, between the pixels. The isolation portion 324 can reduce electrical crosstalk or optical crosstalk between the pixels. The isolation portion 324 has a groove, a recess, or a through hole and a film in which the groove, the recess, or the through hole is embedded. Hereinafter, for ease of the description, the groove, the recess, or the through hole is referred to as the groove. The isolation portion 324 can be formed by embedding the third film 323 in the groove or the recess formed by removing part of the semiconductor layer 301. The third film 323 may have a lamination structure including a plurality of layers. For example, the third film 323 may include a layer functioning as a pinning film, a layer functioning as an antireflection layer, and a layer for planarization. According to the present embodiment, the isolation portion 324 may include a light shielding member in addition to the third film 323. The light shielding member may be a material having a light shielding property, for example, a conductor film 331. The third film 323 is disposed so that a pinning film and an insulation layer are laminated in this order and the conductor film 331 is surrounded. The specific configuration will be described later. The isolation portion 324 extends through the first film 321 and the second film 322 and extends through the semiconductor layer 301. The third film 323 is disposed from the groove included in the isolation portion 324 onto the second surface P2 of the semiconductor layer 301 along the second surface P2. The third film 323 covers a side surface and a bottom surface of the groove of the semiconductor layer 301 included in the isolation portions 324 and extends between the second film 322 and the fourth film 326. The isolation portion 324 does not necessarily extend through the semiconductor layer 301. The conductor film 331 is cut at a position where the groove is filled. Here, an upper surface of the isolation portion 324 is defined as a third surface P3.

Here, the positional relationship between the isolation portion 324 and the uneven portion 325 is described. The upper surface of the isolation portion 324 is positioned at the third surface P3 and an upper surface of the uneven portion 325 is positioned at the second surface P2. When the isolation portion 324 is positioned further to the microlens 329 side than the uneven portion 325 as described above, mixing of stray light diffracted or reflected by the uneven portion 325 into the adjacent pixel can be reduced.

With such a configuration of the isolation portion 324, the photoelectric conversion apparatus in which optical crosstalk is reduced can be provided.

FIG. 6B is a schematic plan view of two pixels of the photoelectric conversion apparatus. Here, for description, only the uneven portions 325, the isolation portions 324, the microlenses 329, the fourth semiconductor regions 314, and fifth semiconductor regions 315 are illustrated. For the isolation portions 324, only the grooves and the third film 323 provided in the groove are illustrated. The isolation portions 324 surround the APDs and form a lattice shape in plan view. The fifth semiconductor regions 315 are disposed along side surfaces of the grooves of the isolation portions 324 and can reduce noise from the grooves. The uneven portions 325 are each disposed at a position mainly superposed on a corresponding one of the fourth semiconductor regions 314 and separated from a corresponding one of the isolation portions 324. The isolation portion 324 does not necessarily completely surround the APD. The isolation portion 324 surrounding the APD may be partly discontinued in the surrounding direction, or the APD may be interposed between the isolation portion 324 disposed only for the opposite side portions of the APD. The uneven portion 325 may be in contact with the isolation portion 324.

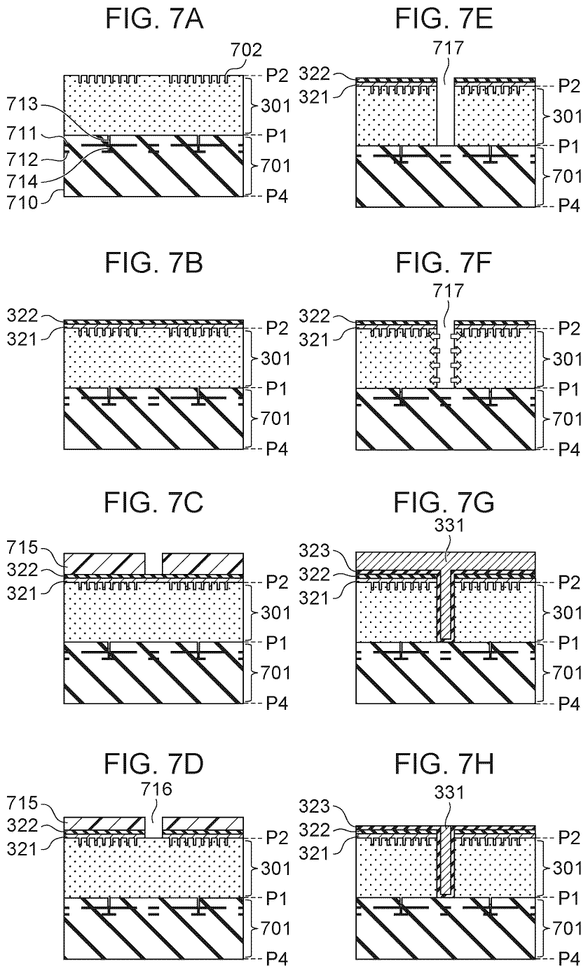

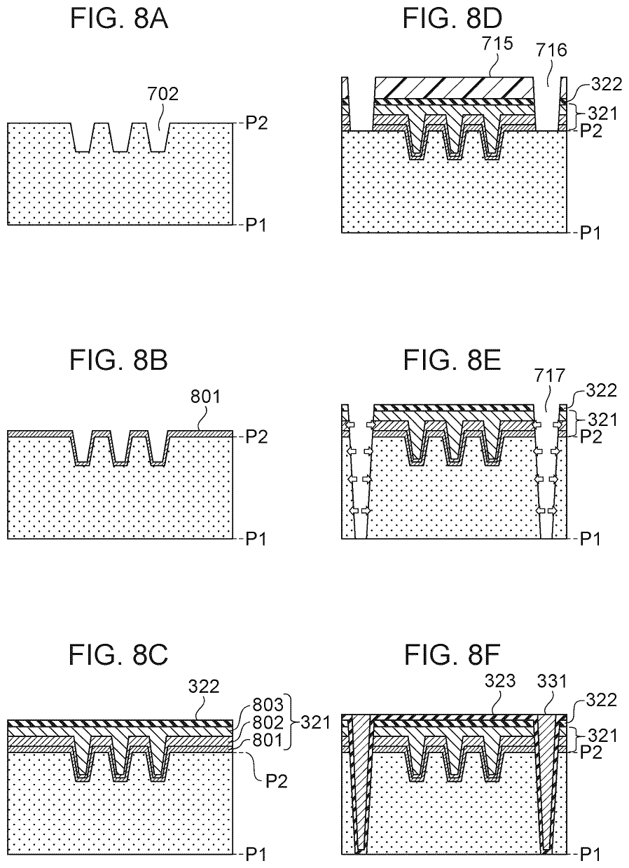

A method for manufacturing the photoelectric conversion apparatus according to the present embodiment is described with reference to FIGS. 7A to 8F. FIGS. 7A to 7H are schematic sectional diagrams illustrating a method for manufacturing the isolation portion 324 and the uneven portion 325. FIGS. 7A to 7H correspond to FIG. 6A, illustrating the section of two pixels. FIGS. 7A to 7H also illustrate a wiring structure 701 omitted from FIG. 6A. In the following description, for ease of description, a member may be denoted by the same reference numeral before and after processing performed on the member.

First, a plurality of semiconductor regions are formed in the semiconductor substrate and the wiring structure 701 is formed on the surface of the semiconductor substrate. The rear surface side of the semiconductor substrate is thinned to form the semiconductor layer 301. The wiring structure 701 includes wiring layers, plugs and an insulator portion 710. The wiring structure 701 includes a first wiring layer 711 and a second wiring layer 712. The first wiring layer 711 is positioned between the second wiring layer 712 and the first surface P1. The wiring structure 701 may include three or more wiring layers. Each of the wiring layers includes a plurality of lines. As the plugs, the wiring structure 701 includes a contact plug 713 for electrical connection between the first wiring layer 711 and the semiconductor layer 301 and a via plug 714 for electrical connection between the first wiring layer 711 and the second wiring layer 712. The wiring structure 701 may include plugs other than the illustrated plugs. The wiring structure 701 includes the insulator portion 710. The insulator portion 710 may include a plurality of insulation layers. The wiring structure 701 have a fourth surface P4 on the opposite side from the first surface P1. Another semiconductor substrate may be provided on the fourth surface P4. The configuration having been described is a configuration of a rear-surface-side photoelectric conversion apparatus can be manufactured through processes of the rear-surface-side photoelectric conversion apparatus. Thus, description is omitted.

Next, grooves 702 for the uneven portions 325 are formed in the second surface P2 of the semiconductor layer 301 (FIG. 7A). Each groove 702 is formed by isotropic etching performed on the semiconductor layer 301 with a photoresist as a mask. The first film 321 is formed so as to fill the grooves 702. As described above, the first film 321 may include a plurality of layers. When an upper surface of the first film 321 is not flat after the grooves 702 have been filled, a planarization process is performed on the upper surface of the first film 321. Here, the second film 322 is formed on the first film 321.

A photoresist pattern 715 for forming the isolation portion 324 is formed on the second film 322 (FIG. 7C). The anisotropic etching is performed on the second film 322, the first film 321, and the semiconductor layer 301 with the photoresist pattern 715 as the mask. First, the etching is performed under the conditions for removing the second film 322 and the first film 321 so as to form a groove 716 (FIG. 7D). Then, the etching is performed under the conditions for removing the semiconductor layer 301 so as to form a groove 717.

Here, during the removal of the semiconductor layer 301, the photoresist pattern 715 may be used as the mask or the second film 322 or the first film 321 may be used as the mask depending on etching conditions. The photoresist pattern 715 is removed to acquire a configuration illustrated in FIG. 7E.

Here, the isotropic etching is further performed on the groove 717 (FIG. 7F). When such a step is performed, the width of the groove 717 can be adjusted. Furthermore, with such a step, a side surface of the groove 717 where the semiconductor layer 301 is exposed is finished, and the dark current can be reduced. Since the width and the depth are greater in the groove 717 than in the groove 702, etching damage is caused more in the groove 717. Thus, the effect of reducing the dark current can be expected more with the groove 717. This isotropic etching may be performed on the groove 702. The dark current ascribable to the groove 702 can be reduced.

Next, the third film 323 and the conductor film 331 are formed (FIG. 7G), and unnecessary part of the conductor film 331 is removed. Thus, a configuration illustrated in FIG. 7H is acquired. Then, the light shield 328 is formed. The light shield 328 may be formed from the conductor film 331 by leaving the conductor film 331 on the third film 323. In this case, the conductor film 331 and the light shield 328 are integrated with each other.

Steps after this are the same as or similar to those of an ordinary method for manufacturing the photoelectric conversion apparatus. In this way, the photoelectric conversion apparatus according to the present embodiment can be manufactured.

With reference to FIGS. 8A to 8F, the further details of the method for manufacturing having been described with reference to FIGS. 7A to 7H are described. FIGS. 8A to 8F are, similarly to FIGS. 7A to 7H, schematic sectional diagrams illustrating the method for manufacturing the isolation portion 324 and the uneven portion 325. FIGS. 8A to 8F focus on the first film 321, the second film 322 and the third film 323, are schematic sectional diagrams for a single pixel, and illustrate only a portion around the semiconductor layer 301.

FIG. 8A illustrates a state similar to or the same as the state illustrated in FIG. 7A. FIGS. 8B and 8C illustrate the formation of the first film 321 illustrated in FIG. 7B. The first film 321 includes three layers, that is, a first layer 801, a second layer 802, and a third layer 803. The first layer 801 is formed so as to cover the entirety of the bottom surface and the side surface of the groove 702, covering at least part of the bottom surface and part of the side surface of the groove 702. The first layer 801 is, for example, a pinning layer. The pinning layer has the function of reducing generation of dark current at an interface portion with the semiconductor layer 301. The pinning layer is formed of, for example, a high-dielectric material having negative fixed charges. Examples of the pinning layer include, for example, aluminum oxide, hafnium oxide, zirconium dioxide, tantalum oxide, and the like. The pinning layer can be manufactured by using, for example, an atomic layer deposition (ALD) apparatus or the like. Here, it is assumed that the first layer 801 is aluminum oxide. Next, the second layer 802 is formed on the first layer 801. The second layer 802 is, for example, an antireflection layer. The material and the thickness of the second layer 802 can be selected in consideration of the refractive indices or the like of the semiconductor layer 301, the first layer 801, and the third layer 803. Examples of the second layer 802 may include, for example, tantalum oxide, titanium oxide, zirconium dioxide, aluminum oxide, and the like. The second layer 802 may be tantalum oxide. The third layer 803 is formed on the second layer 802. When such an antireflection layer is provided, reflection of the incident light into the uneven portion 325 and the second surface P2 can be reduced. The third layer 803 is a layer for embedding. Examples of the third layer 803 include, for example, silicon oxide, silicon oxynitride, and silicon nitride. Here, it is assumed that the third layer 803 is silicon oxide. A planarization process such as chemical mechanical polishing (CMP) is performed on the third layer 803 according to need. An upper surface of the third layer 803 is planarized. Here, the thickness of the first layer 801 is smaller than the thickness of the second layer 802, and the thickness of the second layer 802 is smaller than the thickness of the third layer 803. The third layer 803 may have therein an air gap into which air is trapped. After that, the second film 322 is formed on the first film 321.

The semiconductor layer 301 is single crystal silicon (refractive index of about 4) and the third layer 803 is silicon oxide (refractive index of about 1.8). Thus, the material of the second layer 802 may be selected from materials having a refractive index of an intermediate value.

FIG. 8D illustrates a state similar to or the same as the state illustrated in FIG. 7D. The anisotropic etching is performed with the photoresist pattern 715 as the mask to form the groove 716. Here, the second film 322, the first layer 801 of the first film 321, the second layer 802 of the first film 321, and the third layer 803 of the first film 321 are formed of materials different from each other. Thus, each layer is usable as an etching stopper when the etching is performed under the conditions for different etching selectivity ratios. By using such a method, highly accurate etching can be performed.

Next, FIG. 8E illustrates a state similar to or the same as the state illustrated in FIG. 7F. The anisotropic etching is performed on the semiconductor layer 301 from the state of the groove 716 illustrated in FIG. 7E so as to form the groove 717. The isotropic etching is performed on the semiconductor layer 301 while the grooves 717 are exposed as illustrated in FIG. 8E. When such a step is performed, the width of the groove 717 can be adjusted as described above. Furthermore, the dark current ascribable to the groove 717 can be reduced.

Next, as illustrated in FIG. 8F, the third film 323 is formed so as to cover the groove 717 and the second film 322, and the conductor film 331 is formed. As described above, unnecessary part of the conductor film 331 can be removed.

With such a configuration, it can be said that the isolation portion 324 is provided at an opening of the first film 321. The upper surface of the isolation portion 324 is positioned above the first film 321 in which the layers of different refractive indices are laminated together. This can reduce lateral reflection or propagation of the light at the interface of the first film 321, the interface of the second film 322, and the uneven portion 325 due to phenomena such as reflection, refraction, diffraction, and the like. Also in the configuration without the uneven portion 325, the entrance of the stray light generated by the reflection or the like into other pixels can be reduced.

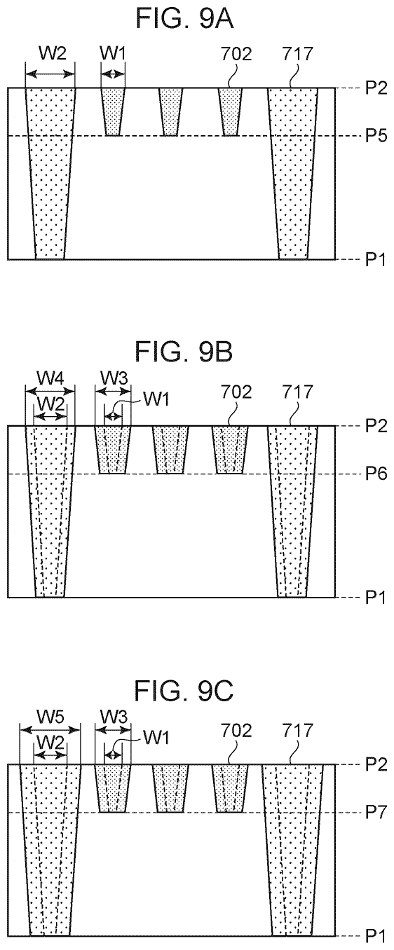

Next, the isotropic etching is described with reference to FIGS. 9A to 9C. FIGS. 9A, 9B, and 9C are schematic sectional diagrams of a single pixel of the photoelectric conversion apparatus for the description of the widths of the grooves of the isolation portion 324 and the uneven portion 325.

FIG. 9A illustrates the widths and lengths of the groove 702 and the groove 717 when the groove 702 is formed simultaneously with the groove 717 by the anisotropic etching. The groove 702 have a length from the position of the second surface P2 to the position of a fifth surface P5. It can be said that the groove 702 has a depth from the second surface P2 to the fifth surface P5. The groove 702 has a width W1 in a direction along the second surface P2. The width of the groove 702 may be different from the width W1 between the second surface P2 and the fifth surface P5. Referring to FIG. 9A, the width of the groove 702 reduces from the second surface P2 toward to fifth surface P5. The width of the groove 702 may be greater than the width W1 in part between the second surface P2 to the fifth surface P5. The groove 702 may have an arbitrary structure. The groove 717 has a length from the position of the second surface P2 to the position of the first surface P1. It can be said that the groove 717 has a depth from the second surface P2 to the first surface P1. The groove 717 has a width W2 in a direction along the second surface P2. The width of the groove 717 may be different from the width W2 between the second surface P2 and the first surface P1. Referring to FIG. 9A, the width of the groove 717 reduces from the second surface P2 toward to first surface P1. The width of the groove 717 may be greater than the width W2 in part between the second surface P2 to the first surface P1. The groove 717 may have an arbitrary structure.

FIG. 9B illustrates the shapes of the groove 702 and the groove 717 when the isotropic etching is performed on the groove 702 and the groove 717 after the step illustrated in FIG. 9A. The width of the groove 702 has been changed from the width W1 to a width W3 and the width of the groove 717 has been changed from the width W2 to a width W4. The width W3 is greater than the width W1, and the width W4 is greater than the width W2. In such processing, the dark current in the groove 702 and the groove 717 can be reduced. Furthermore, the widths of the groove 702 and the groove 717 can be highly accurately adjusted. Thus, isolation performance and the sensitivity can be improved. Furthermore, due to the isotropic etching, the bottom surface of the groove 702 are positioned at a sixth surface P6. The sixth surface P6 is positioned closer to the first surface P1 than the fifth surface P5. A bottom surface of the groove 717 are positioned at the first surface P1 in the state of FIG. 9A, and the depth of the groove 717 does not further increase because of the non-existence of the semiconductor layer 301 at the bottom surface. The bottom surface of the groove 717 may be positioned farther from the second surface P2 than the first surface P1 depending on the conditions of the isotropic etching.

FIG. 9C illustrates the shapes of the groove 702 and the groove 717 when the isotropic etching is separately performed on the groove 702 and the groove 717. The width of the groove 702 has been changed from the width W1 to the width W3 and the width of the groove 717 has been changed from the width W2 to a width W5. The width W3 is greater than the width W1, and the width W5 is greater than the width W2. In such processing, the dark current in the groove 702 and the groove 717 can be reduced. Furthermore, the widths of the groove 702 and the groove 717 can be highly accurately adjusted. Thus, isolation performance and the sensitivity can be improved. Furthermore, the isotropic etching is performed in the separate steps. Accordingly, the shape of the groove 702 and the shape of the groove 717 can be separately adjusted.

Here, from the viewpoint of control of the shapes, the etching amount of the conditions of the isotropic etching of the groove 702 may be greater than or equal to the etching amount of the conditions of the isotropic etching of the groove 717. Alternatively, the etching amount of the conditions of the isotropic etching of the groove 702 may be smaller than the etching amount of the conditions of the isotropic etching of the groove 717. In this case, the amount of change in width of the groove 702 can be reduced. The reason for this is that, since the groove 702 is to serve as the uneven portion 325 provided in a light receiving surface, improvement of the sensitivity can be expected more as the width of the groove 702 becomes smaller. Furthermore, since the groove 702 is provided in the light receiving surface, damage caused by the etching can be reduced, and the dark current can be reduced.

Referring to FIGS. 9A and 9C, for example, the width W1 is about 0.06 μm and the width W3 is about 0.15 μm. For example, the width W2 is about 0.25 μm and the width W5 is about 0.36 μm. This suppresses the generation of thermally excited charges in the interfaces of the semiconductor layer 301 of the uneven portions 325 or the isolation portions 324, and the dark current is reduced. The ratio between the width W1 of the groove 702 and the width W5 of the groove 717 is arbitrarily selectable in a range from 1:2 to 1:10. That is, the width of the groove of each isolation portion 324 and the width of the groove of each uneven portion 325 are arbitrarily selectable in the following range: the width of the groove of the isolation portion 324 is greater than or equal to twice the width of the groove of the uneven portion 325 and smaller than or equal to ten times the width of the groove of the uneven portion 325. The groove 717 can be formed with a depth of 0.1 to 0.6 μm. For acquiring sufficient diffraction light of the incident light due to the uneven portion 325, the depth of the groove 717 can be greater than the width of the groove 717. Regarding the width of the grooves, this width is arbitrarily controllable depending on a method of the isotropic etching after the anisotropic etching processing. An appropriate amount of the etching can be determined by totally assessing the dark current, the embeddability of the embedded material, and the optical characteristics of the embedded material. In the isotropic etching, the depths of the grooves 702 and the grooves 717 can be similarly changed.

As has been described, when the isolation portion 324 is positioned further to the microlens 329 side than the uneven portion 325, mixing of stray light diffracted or reflected by the uneven portion 325 into the adjacent pixel can be reduced. With such a configuration of the isolation portion 324, the photoelectric conversion apparatus in which optical crosstalk is reduced can be provided. Furthermore, when the isotropic etching is further performed on the groove 702 of the uneven portion 325 and the groove 717 of the isolation portion 324, the shapes of the groove 702 and the groove 717 can be adjusted. Thus, the photoelectric conversion apparatus including the more desirable uneven portion 325 and the more desirable isolation portion 324 can be provided.

Furthermore, when the isotropic etching is further performed on the groove 702 of the uneven portion 325 and the groove 717 of the isolation portion 324, the dark current can be reduced. Thus, the photoelectric conversion apparatus with the reduced dark current can be provided. Furthermore, when the isotropic etching is performed on the groove 702 and the groove 717 in the separate steps, the shapes of the groove 702 and the groove 717 can be controlled with higher accuracy. Thus, the photoelectric conversion apparatus including the more desirable uneven portion 325 and the more desirable isolation portion 324 can be provided. Furthermore, when the etching amount of the groove 717 is increased to an amount greater than the etching amount of the groove 702 in performing the isotropic etching on the groove 702 and the groove 717 in the separate steps, the shape of the groove 717 can be controlled while the dark current in the light receiving surface can be reduced. Accordingly, the photoelectric conversion apparatus with the reduced dark current can be provided.

### Second Embodiment

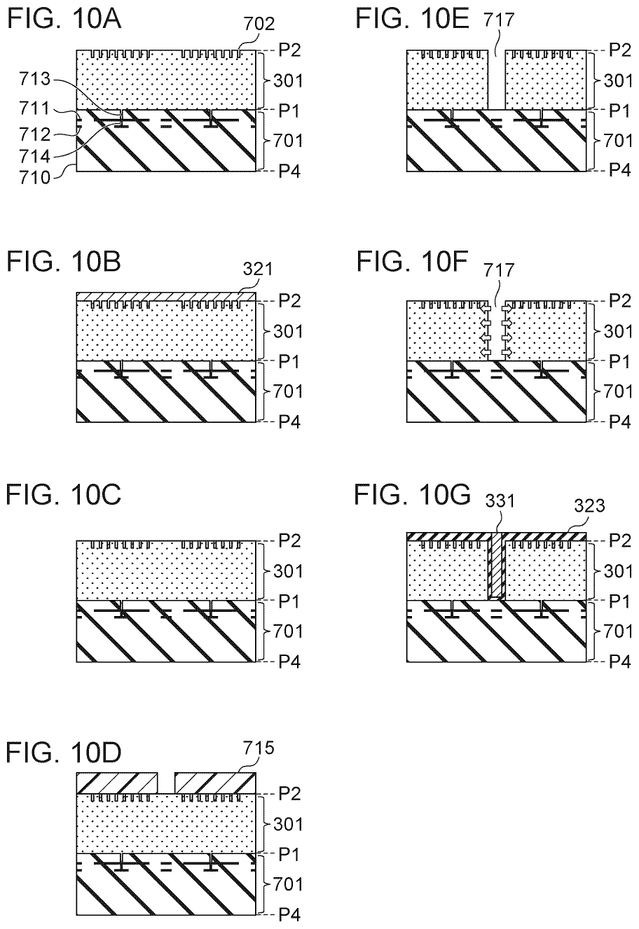

A second embodiment is described with reference to FIGS. 10A to 10G. FIGS. 10A to 10G are schematic sectional diagrams illustrating the method for manufacturing the photoelectric conversion apparatus corresponding to FIGS. 7A to 7H according to the first embodiment. Referring to FIGS. 10A to 10G, description of steps similar to or the same as those of FIGS. 10A to 10G is omitted. The difference between the second embodiment and the first embodiment is the difference in structure of the first film 321 and the second film 322.

A step illustrated in FIG. 10A is similar to or the same as that of FIG. 7A. Thus, the description of FIG. 10A is omitted. A step illustrated in FIG. 10B is similar to or the same as that of FIG. 7B. Thus, the description of FIG. 10B is omitted. Referring to FIG. 10B, a planarization process such as CMP is performed on the first film 321. Then, the first film 321 other than part thereof embedded in the groove 702 is removed (FIG. 10C). Here, the second film 322 may be formed.

After such steps, the photoresist pattern 715 is formed for the formation of the groove 717 in a similar or the same manner as that illustrated in FIG. 7D (FIG. 10D), and the groove 717 is formed by the anisotropic etching (FIG. 10D). Referring to FIG. 10F, the isotropic etching is performed on the groove 717 in a similar or the same manner as that illustrated in FIG. 7F. Then, the third film 323 and the conductor film 331 are formed in a similar or the same manner as those illustrated in FIGS. 7G and 7H (FIG. 10G).

As has been described, the steps of cutting the first film 321 and forming the third film 323 on the second surface P2 may be provided. Similarly to or in the same manner as the first embodiment, also according to the present embodiment, the photoelectric conversion apparatus that produces at least one of the following effects can be provided: the effect of reducing optical crosstalk; the effect of including the more desirable uneven portion 325 and the more desirable isolation portion 324; and the effect of reducing the dark current.

### Third Embodiment

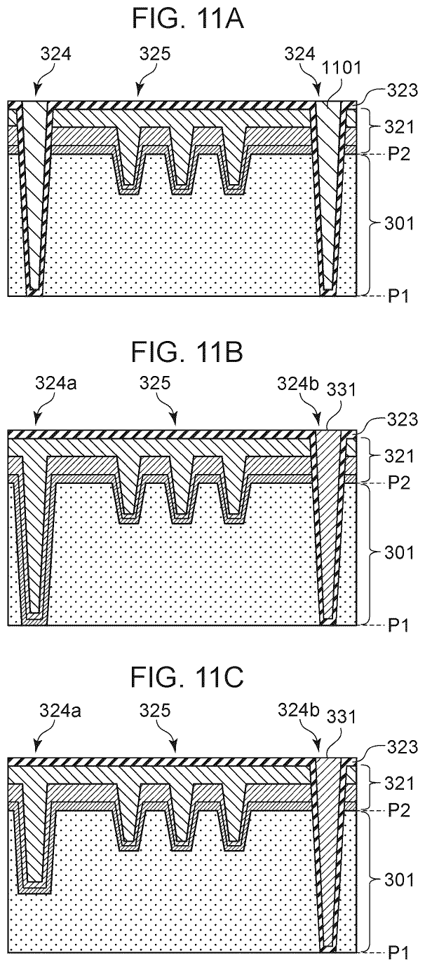

A third embodiment is described with reference to FIGS. 11A to 11C. FIGS. 11A to 11C are schematic sectional diagrams illustrating the photoelectric conversion apparatus corresponding to FIG. 8F of the first embodiment. Referring to FIGS. 11A to 11C, description of configurations similar to or the same as those of FIG. 8F is omitted. The difference between the third embodiment and the first embodiment is that, in the third embodiment, the second film 322 is not provided and the structure of the isolation portion 324 is different from that of the first embodiment.

First, FIG. 11A illustrates a single pixel of the semiconductor layer 301 of the photoelectric conversion apparatus similarly to or in the same manner as that illustrated in FIG. 8F. The difference between the configuration illustrated in FIG. 11B and the configuration illustrated in FIG. 8F is that the conductor film 331 with which the groove 717 of the isolation portion 324 is filled is changed to a different dielectric film 1101. Instead of the conductor film 331, the dielectric film 1101 may be disposed in the groove 717. Furthermore, the dielectric film 1101 with which the groove 717 is filled may include a gap. Furthermore, the dielectric film 1101 may be disposed along the side surface of the groove 717 or disposed part of the side surface of the groove 717.

FIG. 11B illustrates a single pixel of the semiconductor layer 301 of the photoelectric conversion apparatus similarly to or in the same manner as that illustrated in FIG. 8F. The difference between the configuration illustrated in FIG. 11B and the configuration illustrated in FIG. 8F is that the structures of the isolation portions 324 on the left side and the right side in the page of the drawing are different from each other. Referring to FIG. 11B, an isolation portion 324a is formed and filled simultaneously with the groove of the uneven portion 325. Accordingly, the isolation portion 324a is filled with the first film 321. An isolation portion 324b is formed after the first film 321 has been formed. The isolation portion 324b has the groove 717, the third film 323 with which the groove 717 is filled, and the conductor film 331. When the uneven portion 325 and the isolation portions 324 are formed in separate steps as described above, an arbitrary position of the isolation portions 324 can be formed simultaneously with the uneven portion 325. The structure of the isolation portions 324 can be deformed at an arbitrary position as described above. This is desirable when variation of the isolation performance among the APDs is wanted. For example, the following configuration is possible: the isolation portion 324a illustrated in FIG. 11B is disposed between two APDs disposed for a single color filter; and the isolation portion 324b illustrated in FIG. 11B is disposed in a space formed with another APD. Alternatively, the following configuration is possible: the isolation portion 324a illustrated in FIG. 11B is disposed between two APDs disposed for a single microlens; and the isolation portion 324b illustrated in FIG. 11B is disposed in a space formed with another APD.

FIG. 11C illustrates a single pixel of the semiconductor layer 301 of the photoelectric conversion apparatus similarly to or in the same manner as that illustrated in FIG. 11B. The difference between the configuration illustrated in FIG. 11C and the configuration illustrated in FIG. 11B is that, in the configuration illustrated in FIG. 11C, the depth of the isolation portion 324a is different from the depth of the isolation portion 324b. When the isolation portions 324a and 324b are formed in separate steps, the depth and the width of the isolation portion 324a can be different from those of the isolation portion 324b. Thus, when the variation of the isolation performance is wanted as described above, desirable isolation portions can be provided.

### Fourth Embodiment

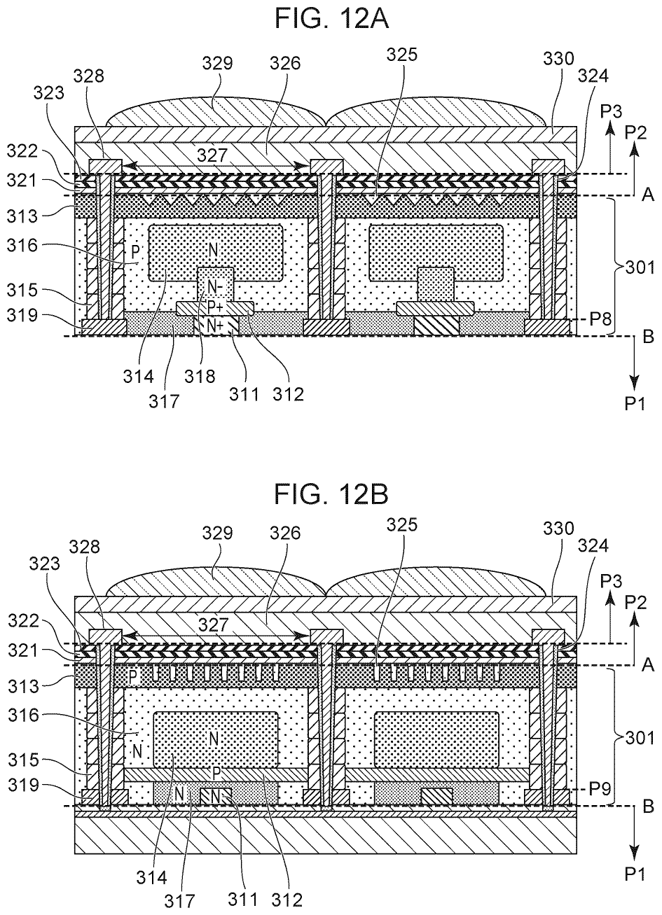

A fourth embodiment is described with reference to FIGS. 12A and 12B. FIGS. 12A and 12B correspond to FIG. 6A according to the first embodiment and are schematic sectional views illustrating the photoelectric conversion apparatus. Referring to FIGS. 12A and 12B, description of configurations similar to or the same as those of FIG. 6A is omitted.

The photoelectric conversion apparatus illustrated in FIG. 12A is different from the photoelectric conversion apparatus illustrated in FIG. 6A in the configuration of the plurality of semiconductor regions, the configuration of the uneven portion 325, and the depth of the isolation portion 324. Compared to the configuration illustrated in FIG. 6A, the size and the concentration of the first semiconductor region 311 increase. The concentration of the second semiconductor region 312 increases. The conductivity type of the sixth semiconductor region 316 changes to the P type, and the size of the seventh semiconductor region 317 increases. Furthermore, the eighth semiconductor region 318 of the N type is added. Provision to the APDs having such a configuration is possible.

Furthermore, the uneven portion 325 has an acutely angled pyramid shape compared to that illustrated in FIG. 6A. In such a configuration, the sensitivity can be improved. The isolation portion 324 does not extend throughout the semiconductor layer 301. A bottom surface of the isolation portion 324 is positioned at a seventh surface P7. The P-type ninth semiconductor region 319 is disposed between the isolation portion 324 and the first surface P1. When the ninth semiconductor region 319 is disposed, generation of noise on the first surface P1 side can be reduced.

The photoelectric conversion apparatus illustrated in FIG. 12B is different from the photoelectric conversion apparatus illustrated in FIG. 6A in that the photoelectric conversion apparatus illustrated in FIG. 12B includes insulation films 1201, 1202, and 1203 disposed on the first surface P1 side and the configuration of the isolation portion 324 of the photoelectric conversion apparatus illustrated in FIG. 12B is different from that of the photoelectric conversion apparatus illustrated in FIG. 6A. The isolation portion 324 illustrated in FIG. 12B extend through the first surface P1 of the semiconductor layer 301 and the insulation film 1201 and are in contact with the insulation film 1202. The so-called insulation film 1202 can function as the etching stop film. Such a configuration improves accuracy of the depth of the groove 717. Here, the insulation films 1201, 1202, and 1203 are, for example, silicon oxide, silicon oxynitride, silicon nitride, or the like. For example, the insulation films 1201 and 1203 may be silicon oxide, and the insulation film 1202 may be silicon nitride.

Furthermore, referring to FIG. 12B, the angle of the side surface of the isolation portion 324 increases or a reduction rate of the width of the side surface of the isolation portion 324 increases at the seventh surface P7. The angle of the side surface means, for example, an angle formed between a perpendicular to the first surface P1 and the side surface. Such a shape can be acquired by switching the etching conditions midway during the formation of the groove 717 of the isolation portion 324. With such a shape, the size of the isolation portion 324 formed on the first surface P1 side reduces. Thus, the distance from the isolation portion 324 to the avalanche multiplication region can be increased. Accordingly, the photoelectric conversion apparatus with the reduced dark current can be provided.

### Fifth Embodiment

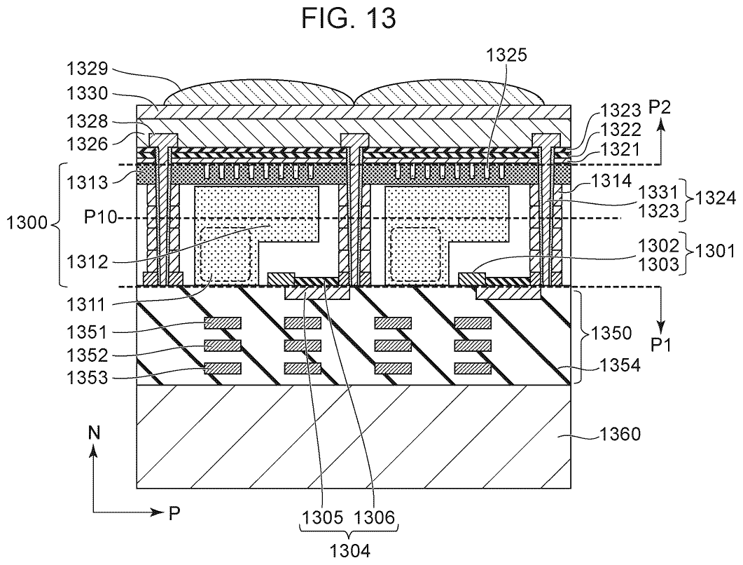

A fifth embodiment is described with reference to FIG. 13. FIG. 13 is a schematic sectional diagram illustrating the photoelectric conversion apparatus corresponding to FIG. 6A of the first embodiment. In FIG. 6A, the photoelectric conversion apparatus includes the APD. The photoelectric conversion apparatus illustrated in FIG. 13 is a complementary metal-oxide semiconductor (CMOS) image sensor including a so-called photodiode (PD). Referring to FIG. 13, a direction P indicates a horizontal direction (in-plane direction), and a direction N indicates a perpendicular direction (normal direction). The perpendicular direction is a direction relative to the second surface P2.

The photoelectric conversion apparatus includes a semiconductor layer 1300 having the first surface P1 and the second surface P2. The semiconductor layer 1300 is, for example, a single-crystal silicon layer. However, the semiconductor layer 1300 is not limited to the single-crystal silicon layer when the semiconductor layer can perform the photoelectric conversion.

An element isolation portion 1301, a wiring structure 1350, and another semiconductor layer 1360 are disposed on the first surface P1 side of the semiconductor layer 1300. The wiring structure 1350 includes wiring layers 1351, 1352, and 1353 and an insulator portion 1354. In FIG. 13, contact plugs and via plugs of the wiring structure 1350 are omitted. The insulator portion 1354 may include a plurality of insulation layers. The semiconductor layer 1360 may be a simple support substrate or provided with a circuit processing signals from the CMOS image sensor. In the case of the latter, the semiconductor layer 1300 and the semiconductor layer 1360 can be electrically connected to each other by using an arbitrary technique. The thickness of the semiconductor layer 1300 is about 1 to 10 μm, and the thickness of the semiconductor layer 1360 is about 50 to 800 μm.

A first film 1321, a second film 1322, a third film 1323, an isolation portion 1324, an uneven portions 1325, a fourth film 1326, a light shield 1328, microlens 1329, and a color filter 1330 are provided on the second surface P2 side of the semiconductor layer 1300. The light shield 1328 has openings. These configurations are similar to or the same as the configuration of the first embodiment. Thus, description of these configurations is omitted.

The semiconductor layer 1300 includes an N-type semiconductor region 1311 included in the PD and an N-type semiconductor region 1312. The semiconductor layer 1300 also includes a P-type semiconductor region 1313 and a P-type semiconductor region 1314. A P-type semiconductor layer may be further provided on the first surface P1 side of the semiconductor region 1311. The PD includes the N-type semiconductor regions including the semiconductor regions 1311 and 1312 and the other P-type semiconductor regions. The semiconductor region 1313 covers each uneven portion 1325 and can reduce the dark current from the uneven portion 1325 and the dark current from the second surface P2. The semiconductor region 1314 covers a side surface of each isolation portion 1324 and can reduce the dark current from the isolation portion 1324.

A transistor including a gate electrode 1305, a channel region 1306, and a source drain region (not illustrated) may be disposed in the semiconductor layer 1300. This transistor is a so-called pixel transistor of the CMOS image sensor. The following configuration may be used: the semiconductor layer 1300 includes only the PD; and the other semiconductor layer includes the pixel transistor and the like.

The element isolation portion 1301 may be disposed on the first surface P1 of the semiconductor layer 1300 and include a groove 1302 and an insulator 1303 disposed in the groove 1302. The element isolation portion 1301 may have, for example, a shallow trench isolation (STI) structure or a local oxidation of silicon (LOCOS) structure. The insulator 1303 is formed of, for example, silicon oxide.

The isolation portion 1324 may include a groove disposed in the semiconductor layer 1300 and a film with which the groove is filled. When a ninth surface P9 is defined so as to be equidistant from the first surface P1 and the second surface P2, the isolation portion 1324 is disposed so as to extend through the ninth surface P9. The isolation portion 1324 includes a third film 1323 and a conductor film 1331. A vacuum space or an air gap formed of gas may be disposed in the groove. Both the gas and a solid such as a film may be disposed in the groove. The solid existing in the groove may be any one of an insulator, a conductor, or a semiconductor. Although silicon oxide is a typical insulator as the solid existing in the groove, silicon nitride, silicon oxynitride, tantalum oxide, hafnium oxide, titanium oxide, or the like can be used. Although metal or polysilicon is a typical conductor as the solid existing in the groove, aluminum, copper, tungsten, titanium, titanium nitride, tantalum, tantalum nitride, metallic silicide, or the like can be used. Although single-crystal silicon is a typical semiconductor as the solid existing in the groove, amorphous silicon may be used. The conductivity type of the semiconductor as the solid existing in the groove can be an opposite conductivity type to the conductivity type of the signal charges accumulated by the photoelectric conversion element, which will be described later. These materials are applicable to the other embodiments.

The uneven portion 1325 may be disposed in the second surface P2 of the semiconductor layer 1300 and include a groove and a film with which the groove is filled. The uneven portion 1325 causes the incident light to scatter and diffract.

In such a CMOS image sensor, when the isolation portion 1324 is positioned further to the microlens 1329 side than the uneven portion 1325, mixing of the stray light diffracted or reflected by the uneven portion 1325 into the adjacent pixel can be reduced. With such a configuration of the isolation portion 1324, the photoelectric conversion apparatus in which optical crosstalk is reduced can be provided. Furthermore, the methods of manufacturing and the modifications described for the other embodiments can be appropriately applied. In the CMOS image sensor, in a configuration including an overflow drain, the isolation characteristics of the isolation portion at a position wanted to be overflowed can be reduced than the isolation characteristics of the other isolation portion. Specifically, the configuration is, for example, as follows: the isolation portion 324a on the left side of the page of FIG. 11B or 11C is provided at a positioned wanted to be overflowed; and the isolation portion 324b on the right side of the page of FIG. 11B or 11C is placed at the other position. Also according to the present embodiment, the effects similar to or the same as the other embodiments can be acquired.

### Sixth Embodiment

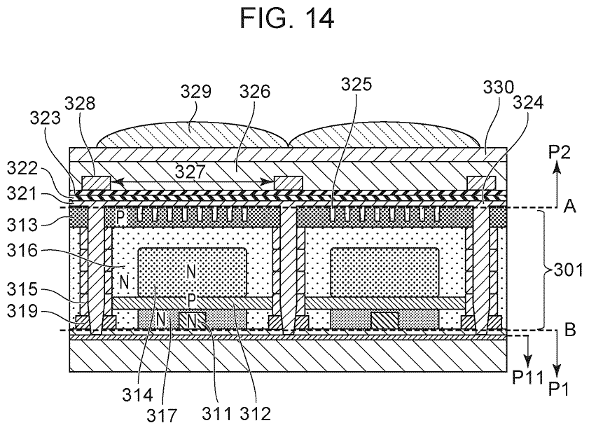

A sixth embodiment is described with reference to FIGS. 14 to 18D. FIG. 14 corresponds to FIG. 6A and is a schematic sectional diagram illustrating the photoelectric conversion apparatus according to the present embodiment. Referring to FIG. 14, description of configurations similar to or the same as those of FIG. 6A is omitted. Unlike the photoelectric conversion apparatus according to the first embodiment, in the photoelectric conversion apparatus according to the present embodiment, the isolation portion 324 and the uneven portion 325 are embedded with the same first film 321 whereas the conductor film 331 disposed in the photoelectric conversion apparatus illustrated in FIG. 6A is not disposed. That is, the upper surface of the isolation portions 324 is, as is the case with the upper surface of the uneven portion 325, positioned at the second surface P2. Here, unlike the first embodiment, the third film 323 extends along the second surface P2. The third film 323 is formed of, for example, silicon oxide, silicon oxynitride, silicon nitride, or the like.

Here, the width of the isolation portion 324 illustrated in FIG. 14 changes from the ninth semiconductor region 319, and the width is smaller at the first surface P1 than at the second surface P2. Furthermore, a lower surface of the isolation portion 324 extends through the first surface P1 and positioned at an eleventh surface P11. When the width of the isolation portion 324 at the first surface P1 is reduced as described above, the distance from the avalanche multiplication region increases. This can reduce influence of the noise from the isolation portion 324 to the avalanche multiplication region. Furthermore, the width of the ninth semiconductor region 319 can be reduced compared to the first embodiment. This can reduce influence of the electric field and the like exerted on the avalanche multiplication region by the ninth semiconductor region 319.

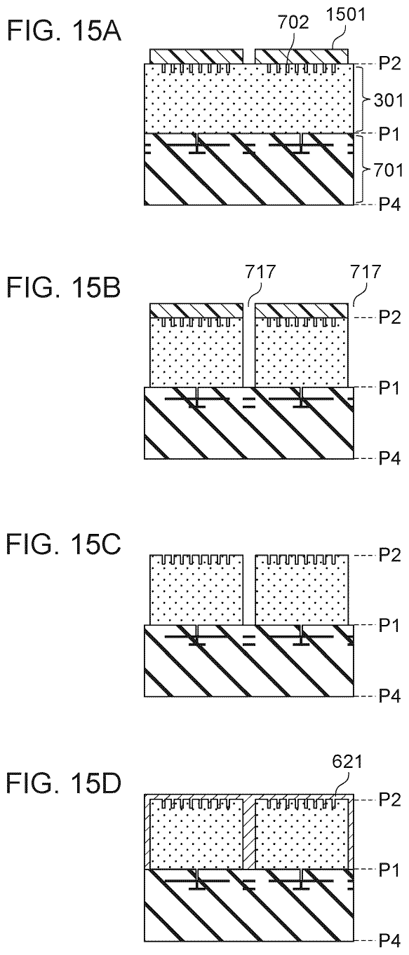

FIGS. 15A to 15D are schematic sectional diagrams illustrating the method for manufacturing the photoelectric conversion apparatus configured as described above. FIGS. 15A to 15D correspond to FIGS. 7A to 7H and are schematic sectional diagrams illustrating a method for manufacturing the isolation portion 324 and the uneven portion 325. Referring to FIGS. 15A to 15D, description of configurations similar to or the same as those of FIGS. 7A to 7H is omitted. Referring to FIG. 15A, the groove 702 is formed in the semiconductor layer 301. A photoresist pattern 1501 is formed above the groove 702. The anisotropic etching is performed on the semiconductor layer 301 with the photoresist pattern 1501 as the mask to form the groove 717 for the isolation portion 324 (FIG. 15B). Furthermore, the isotropic etching is performed after the photoresist pattern 1501 has been removed (FIG. 15C). Then, the first film 321 is formed such that the groove 702 and the groove 717 are filled with the first film 321 (FIG. 15D). Steps after this are performed by the method for manufacturing the photoelectric conversion apparatus. The upper surface of the first film 321 is planarized, and the second film 322, the third film 323, and the light shield 328 are formed. The fourth film 326 covering the light shield 328 is formed. The color filter 330 and the microlens 329 are formed. In such steps, the photoelectric conversion apparatus according to the present embodiment can be manufactured.

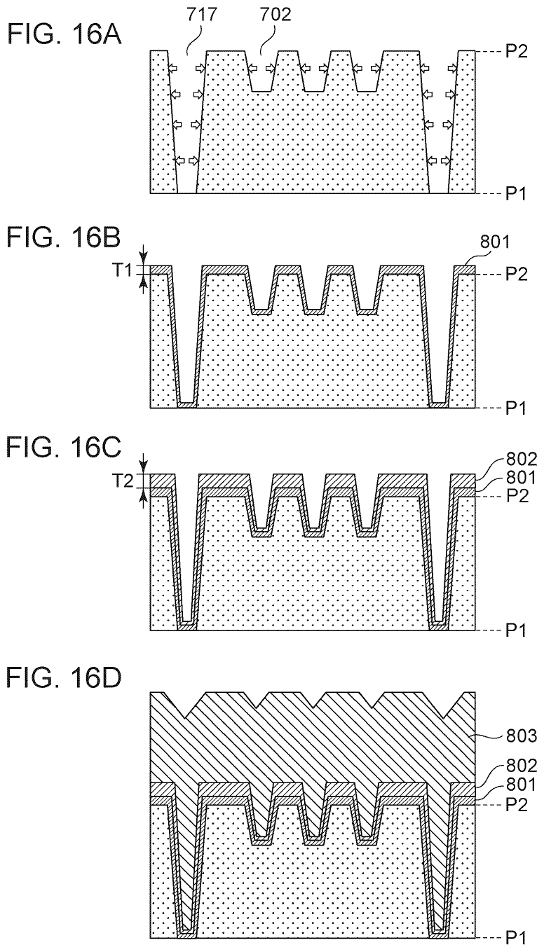

FIGS. 16A to 16D are schematic sectional diagrams illustrating the further details of the method for manufacturing having been described with reference to FIGS. 15A to 15D.

FIGS. 16A to 16D correspond to FIGS. 8A to 8F of the first embodiment and are schematic sectional diagrams illustrating the method for manufacturing the isolation portion 324 and the uneven portion 325. FIGS. 16A to 16D focus on the first film 321, are schematic sectional diagrams for a single pixel, and illustrate only a portion around the semiconductor layer 301. FIG. 16A illustrates a step of performing the isotropic etching simultaneously on the groove 702 and the groove 717. After the process has been performed as described above, the first layer 801 of the first film 321 is formed (FIG. 16B). Then, the second layer 802 is formed (FIG. 16C). The first layer 801 and the second layer 802 may be similar to or the same as those used in the first embodiment. The first layer 801 or the second layer 802 is not necessarily formed. According to the present embodiment, a thickness T2 of the second layer 802 is greater than a thickness T1 of the first layer 801. The reason for this is that the thickness of the second layer 802 is adjusted with consideration for the optical characteristics. Furthermore, the thickness of the first layer 801 is greater in portions formed on the second surface P2 along the second surface P2 than in portions formed on the side surface of the groove 702 or the groove 717. With such a configuration, a film having high adhesiveness can be formed. The thickness of the second layer 802 is greater in portions formed on the second surface P2 along the second surface P2 than in portions formed on the side surface of the groove 702 or the groove 717. With such a configuration, reflection can be reduced with respect to the incident light. Next, the third layer 803 is formed. The third layer 803 is formed such that the groove 702 and the groove 717 are filled with the third layer 803. Thus, the third layer 803 is a thick layer formed above the second surface P2. After that, the third layer 803 can be removed by the CMP method or an etching method and planarized. In this way, the isolation portion 324 and the uneven portion 325 according to the present embodiment are formed.

### Seventh Embodiment

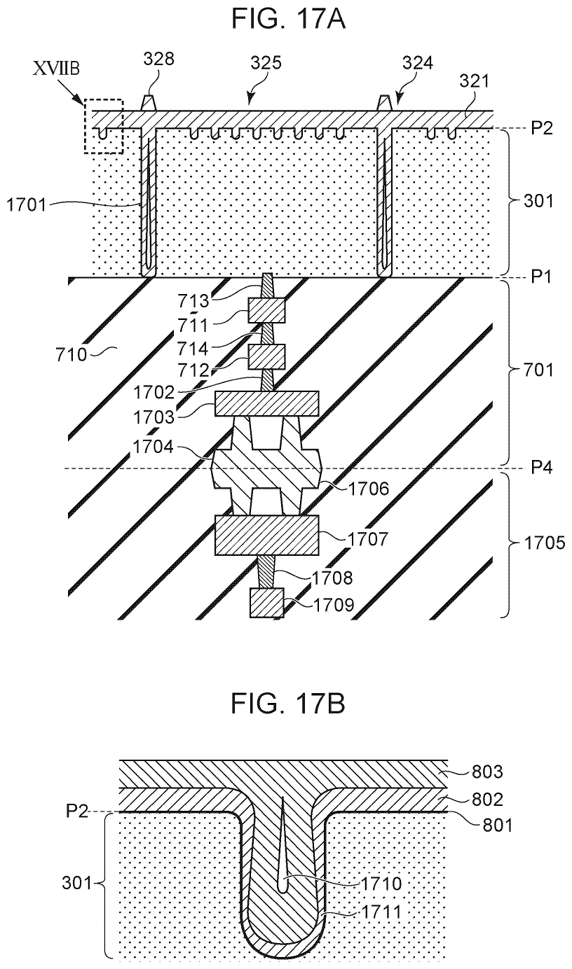

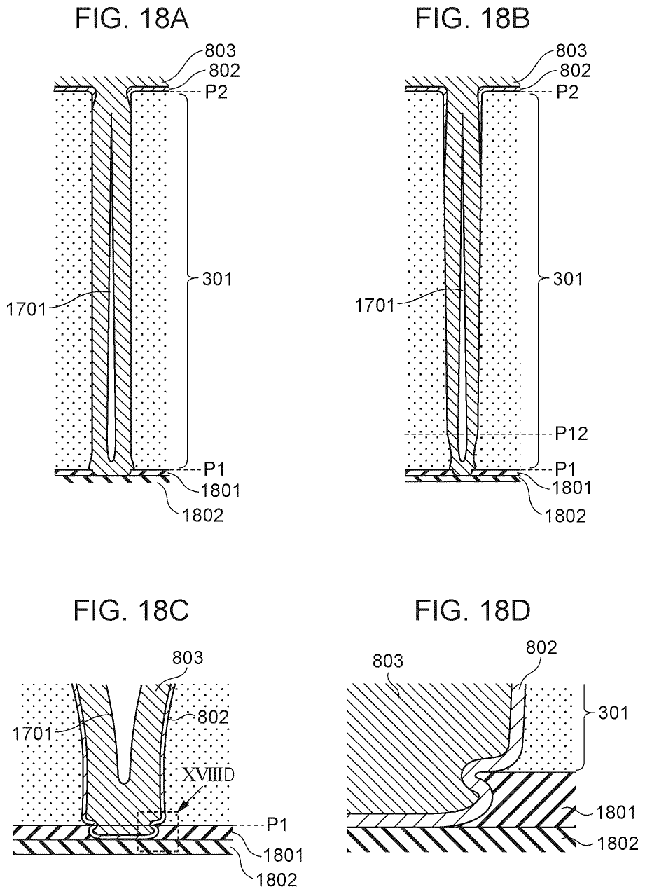

A seventh embodiment is described with reference to FIGS. 17A to 18D. FIG. 17A corresponds to FIG. 14 and is a schematic sectional diagram illustrating the photoelectric conversion apparatus according to the present embodiment. Referring to FIG. 17A, description of configurations similar to or the same as those of FIG. 14 is omitted. FIG. 17A illustrates the semiconductor layer 301, the wiring structure 701 not illustrated in FIG. 14, and another wiring structure 1705.

The wiring structure 701 includes wiring layers, plugs, and the insulator portion 710. Regarding the wiring structure 701, description of the elements having been described with reference to FIGS. 7A to 7H is omitted. The wiring structure 701 includes the first wiring layer 711, the second wiring layer 712, a third wiring layer 1703, the contact plug 713, the via plug 714, and a via plug 1702. The wiring layers and the plugs may be integrally formed. Furthermore, a metal portion 1704 is included for junction. The metal portion 1704 may be provided also for establishing electrical connection. Furthermore, the metal portion 1704 may be provided for so-called hybrid bonding for junction of metal and an insulator. The wiring structure 701 is in contact with the other wiring structure 1705 with the fourth surface P4 as a junction surface. The other wiring structure 1705 includes a wiring layer 1709, a wiring layer 1707, a via plug 1708, and a metal portion 1706. These elements have similar or the same functions as the functions of the corresponding elements of the wiring structure 701.

The semiconductor layer 301 includes the isolation portions 324 and the uneven portions 325. An end portion of each isolation portion 324 on the first surface P1 side is rounded. The side surface of the isolation portion 324 includes a curve near the first surface P1. Furthermore, an air gap 1701 is provided in the isolation portion 324. An end portion of each uneven portion 325 on the first surface P1 side is rounded. A side surface of the uneven portion 325 includes a curve on the first surface P1 side. FIG. 17B illustrates region XVIIB surrounding one of the uneven portions 325 with a dotted line.

FIG. 17B is an enlarged schematic diagram of the uneven portion 325 in region XVIIB illustrated in FIG. 17A. The first layer 801 and the second layer 802 are disposed along the shape of the groove 702 formed in the semiconductor layer 301. The first layer 801 and the second layer 802 are disposed on the semiconductor layer 301 along the second surface P2. It can also be described that the first layer 801 and the second layer 802 are disposed on the surface of the semiconductor layer 301 in a conformal manner. The third layer 803 is disposed such that the groove 702 is filled with the third layer 803, and the upper surface of the third layer 803 is planarized. Here, a film thickness of the first layer 801 is smaller than the film thickness of the second layer 802, and the film thickness of the second layer 802 is smaller than a film thickness of the third layer 803. An air gap 1710 is disposed in the groove 702 so as to be surrounded by the third layer 803. The air gap 1710 is not necessarily provided. The film thickness of a portion of the second layer 802 positioned on the second surface P2 is greater than the film thickness of a portion of the second layer 802 disposed in the groove 702. With such a configuration, reflection at the light incident surface can be reduced. Furthermore, setting of a large opening of the groove 702 facilitates filling of the groove 702 with the third layer 803 and can increase the likelihood of the refraction and diffraction occurring in the uneven portion 325. Furthermore, the film thickness of the portion of the second layer 802 disposed along the side surface of the groove 702 partly reduces at a portion 1711 near the bottom surface. Since the film thickness at a portion in the bottom surface is large, reflection of the incident light entering the bottom surface can be reduced. Each uneven portion 325 has a structure as described above. Although the second layer 802 and the third layer 803 have been described as a continuous layers, connection between the second layer 802 and the third layer 803 may be partly discontinued. For example, the second layer 802 may exist at least at the bottom surface. The second layer 802 can be seemed to be partly discontinued upon observation.

FIG. 18A is an enlarged schematic diagram of the isolation portion 324. FIG. 18C is an enlarged schematic diagram of the bottom surface of the isolation portion 324 illustrated in FIG. 18A. FIG. 18D is an enlarged schematic diagram of region XVIIID illustrated in FIG. 18C. Although illustration of the first layer 801 is omitted from FIGS. 18A, 18C, and 18D, the first layer 801 having a small thickness is formed.

The bottom surface of the isolation portion 324 is in contact with a film 1802. The width of the bottom surface is smaller than the width of the other portion. In particular, as illustrated in FIGS. 18C and 18D, in the isolation portion 324, the width reduces at a boundary portion between the semiconductor layer 301 and the film 1802 and increases again at a film 1801. For example, the width of the isolation portion 324 increases once near the first surface P1, reduces at the boundary between the semiconductor layer 301 and the film 1801, and increases in the film 1801. The film thickness of the portion of the second layer 802 positioned on the second surface P2 is greater than the film thickness of the portion of the second layer 802 positioned on the side surface of the groove. As illustrated in FIG. 18D, part of the film 1801 on the first surface P1 side projects toward the inside of the groove, and the second layer 802 covers the projection of the film 1801.

FIG. 18B is a schematic diagram illustrating a modification of the isolation portion 324 similar to the isolation portion 324 illustrated in FIG. 14. Although illustration of the first layer 801 is also omitted from FIG. 18B, the first layer 801 having a small thickness is formed. The angle of side surface changes at a twelfth surface P12 close to the first surface P1, and the shape of the side surface is tapered along a direction from the twelfth surface P12 toward the first surface P1. The width is reducing along the direction from the twelfth surface P12 toward the first surface P1. The bottom surface, the film 1801, and the film 1802 of the isolation portion 324 may be similar to or the same as those illustrated in FIGS. 18A, 18B, and 18D. Such a configuration can reduce influence of the noise from the isolation portion 324 to the avalanche multiplication region. The configuration can also reduce influence of the electric field and the like exerted on the avalanche multiplication region by the ninth semiconductor region 319.

Here, the film 1801 and the film 1802 can be selectable from, for example, silicon oxide, silicon oxynitride, silicon nitride, and the like. According to the present embodiment, for example, the film 1801 includes silicon oxide, and the film 1802 includes silicon nitride.

### Eighth Embodiment

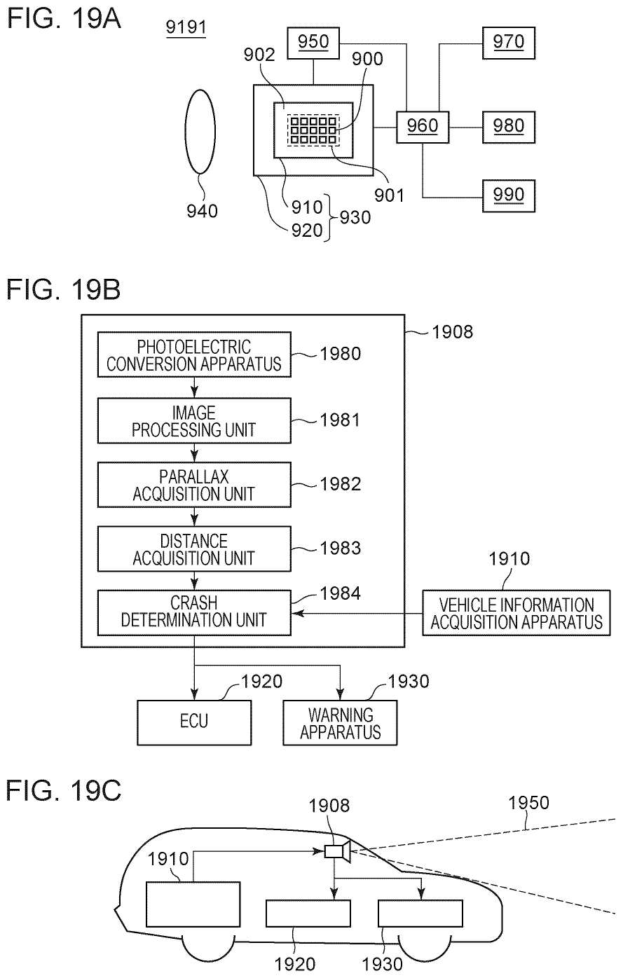

FIG. 19A is a schematic diagram illustrating equipment 9191 including a semiconductor apparatus 930 according to an eighth embodiment. The photoelectric conversion apparatus (image capturing apparatus) according to any of the above-described embodiments can be used for the semiconductor apparatus 930. The equipment 9191 including the semiconductor apparatus 930 is described in detail. The semiconductor apparatus 930 may include a semiconductor device 910. In addition to the semiconductor device 910, the semiconductor apparatus 930 may include a package 920 accommodating the semiconductor device 910. The package 920 may include a base to which the semiconductor device 910 is secured and a lid body that is formed of glass or the like and faces the semiconductor device 910. The package 920 may further include joining members such as bumps and bonding wires that connect terminals provided in the base and terminals provided in the semiconductor device 910 to each other. The semiconductor apparatus 930 includes a region 901 in which a plurality of pixels 900 are disposed and a region 902 around the region 901.

The equipment 9191 may include at least one of an optical apparatus 940, a control apparatus 950, a processing apparatus 960, a display apparatus 970, a storage apparatus 980, and a mechanical apparatus 990. The optical apparatus 940 corresponds to the semiconductor apparatus 930. The optical apparatus 940 includes an optical system that is, for example, a lens, a shutter, or a mirror configured to guide the light to the semiconductor apparatus 930. The control apparatus 950 is configured to control the semiconductor apparatus 930. The control apparatus 950 is a semiconductor apparatus such as, for example, an application specific integrated circuit (ASIC). The processing apparatus 960 is configured to process signals output from the semiconductor apparatus 930. The processing apparatus 960 is a semiconductor apparatus such as a central processing unit (CPU) or an ASIC for configuring an analog front end (AFE) or a digital front end (DFE). The display apparatus 970 is an electroluminescent (EL) display apparatus or a liquid crystal display apparatus configured to display information (images) acquired by the semiconductor apparatus 930. The storage apparatus 980 is an magnetic device or a semiconductor device configured to store the information (images) acquired by the semiconductor apparatus 930. The storage apparatus 980 is volatile memory such as static random access memory (SRAM) or dynamic random access memory (DRAM) or nonvolatile memory such as flash memory or a hard disc drive.

The mechanical apparatus 990 includes a movable unit such as a motor or an engine or a propulsion unit. In the equipment 9191, the signals output from the semiconductor apparatus 930 are displayed in the display apparatus 970 or transmitted to the outside by using a communication apparatus (not illustrated) included in the equipment 9191. Thus, the equipment 9191 can further include the storage apparatus 980 and the processing apparatus 960 in addition to a storage circuit and a computation circuit included in the semiconductor apparatus 930. The mechanical apparatus 990 may be controlled based on the signals output from the semiconductor apparatus 930.

Furthermore, the equipment 9191 is suitable to electronic equipment such as information terminals including an image capturing function (for example, a smartphone and a wearable terminal) or cameras (for example, an interchangeable lens camera, a compact camera, a video camera, and a monitoring camera). The mechanical apparatus 990 in the camera can drive components of the optical apparatus 940 for zooming, focusing, and operation of the shutter. The mechanical apparatus 990 in the camera can move the semiconductor apparatus 930 for anti-vibration operation.

The equipment 9191 can be transport equipment (moving body) such as a vehicle, a ship, or a flight vehicle (drone, aircraft, or the like). The mechanical apparatus 990 in the transport equipment can be used as a moving apparatus.

The equipment 9191 as the transport equipment can be equipment transporting the semiconductor apparatus 930 or equipment that, by using the image capturing function, assists and/or automates driving (piloting). The processing apparatus 960 for assisting and/or automating the driving (piloting) can perform processing for operating the mechanical apparatus 990 as the moving apparatus based on the information acquired by the semiconductor apparatus 930. Alternatively, the equipment 9191 may be medical equipment such as an endoscope, measuring equipment such as a ranging sensor, analytical equipment such as an electron microscope, business equipment such as a copier, or industrial equipment such as a robot.

According to the above-described embodiments, good pixel characteristics can be acquired. Accordingly, the value of the semiconductor apparatus can be increased. Here, the increase in the value corresponds to at least one of the followings: addition of the function; improvement of performance; improvement of characteristics; improvement of reliability; improvement of yields in the manufacture; reduction of environmental burden; cost reduction; size reduction; and weight reduction.

Accordingly, when the semiconductor apparatus 930 according to the present embodiment is used for the equipment 9191, the value of the equipment can be improved. For example, good performance can be acquired when external images of the transport equipment are captured or an external environment is measured with the semiconductor apparatus 930 placed on the transport equipment. Accordingly, in the manufacture or the sales of the transport equipment, determining placement of the semiconductor apparatus according to the present embodiment on the transport equipment is advantageous in that the performance of the transport equipment itself is improved. In particular, the semiconductor apparatus 930 can be used for the transport equipment that assists and/or automates driving of the transport equipment by using the information acquired by the semiconductor apparatus.

A photoelectric conversion system and the moving body according to the present embodiment are described with reference to FIGS. 19B and 19C.

FIGS. 19B and 19C illustrate an example of the photoelectric conversion system for an on-vehicle camera. A photoelectric conversion system 1908 includes a photoelectric conversion apparatus 1980. The photoelectric conversion apparatus 1980 is the photoelectric conversion apparatus (image capturing apparatus) according to any one of the above-described embodiments.

The photoelectric conversion system 1908 includes an image processing unit 1981 and a parallax acquisition unit 1982. The image processing unit 1981 performs image processing on a plurality of pieces of image data acquired by the photoelectric conversion apparatus 1980. The parallax acquisition unit 1982 calculates a parallax (phase difference between parallax images) from the plurality of pieces of image data acquired by the photoelectric conversion system 1908. Here, the photoelectric conversion system 1908 may include an optical system (not illustrated) such as, for example, a lens, a shutter, or a mirror that guides the light to the photoelectric conversion apparatus 1980. Furthermore, a plurality of photoelectric conversion elements substantially conjugate to the pupil of the optical system may be disposed in the pixel included in the photoelectric conversion apparatus 1980. For example, the plurality of photoelectric conversion elements substantially conjugate to the pupil are disposed so as to correspond to a single microlens. When the plurality of photoelectric conversion elements receive pencils of light transmitted through mutually different positions of the pupil of the optical system, the photoelectric conversion apparatus 1980 outputs image data corresponding to the pencils of light transmitted through the different positions. Then, the parallax acquisition unit 1982 may calculate the parallax by using the output image data. Furthermore, the photoelectric conversion system 1908 includes a distance acquisition unit 1983 configured to calculate the distance to an object based on the calculated parallax and a crash determination unit 1984 configured to determine whether a crash possibility exists based on the calculated distance. Here, the parallax acquisition unit 1982 and the distance acquisition unit 1983 are examples of a distance information acquisition unit configured to acquire distance information to the object. That is, the distance information is information about a parallax, a de-focusing amount, a distance to an object, and the like. The crash determination unit 1984 may determine the crash possibility by using any of the pieces of the distance information. The distance information may be acquired by using the TOF. The distance information acquisition unit may be realized by dedicatedly designed hardware or a software module. Furthermore, the distance information acquisition unit may be realized by a field programmable gate array (FPGA), an ASIC, or the like or by a combination of these.

The photoelectric conversion system 1908, which is connected to a vehicle information acquisition apparatus 1910, can acquire vehicle information such as, for example, a vehicle speed, a yaw rate, and a rudder angle. The photoelectric conversion system 1908 is also connected to an electronic control unit (ECU) 1920 being a control apparatus configured to output a control signal generating a braking force for a vehicle based on a determination result with the crash determination unit 1984. The photoelectric conversion system 1908 also connected to a warning apparatus 1930 configured to warn a driver based on the determination result with the crash determination unit 1984. For example, when the crash possibility is high based on the determination result with the crash determination unit 1984, the ECU 1920 brakes, throttles back, suppresses engine output, or performs other operation to control the vehicle for avoiding a crash or reducing damage. The warning apparatus 1930 warns the user by, for example, giving warning with a sound or the like, displaying warning information on a screen of a car navigation system or the like, or applying vibration to a seatbelt or a steering wheel.

According to the present embodiment, an image of a region around the vehicle, for example, a front region or a rear region is captured by the photoelectric conversion system 1908. FIG. 19C illustrates the photoelectric conversion system when the photoelectric conversion system captures an image of a front region of the vehicle (image capturing range 1950). The vehicle information acquisition apparatus 1910 transmits an instruction to the photoelectric conversion system 1908 or the photoelectric conversion apparatus 1980. With such a configuration, accuracy of measuring the distance can be improved.

Although the example of the control for avoiding a crash with another vehicle has been explained in the above description, the configuration described above can be applied to control of automatic driving following another vehicle, control of automatic driving so as not to move out of a lane, and the like. Furthermore, the photoelectric conversion system 1908 can be applied not only to the vehicle such as an automobile but also to, for example, a moving body (moving apparatus) such as a ship, aircraft, or an industrial robot. Such a moving body mainly means either or both of a drive force generation unit configured to generate a drive force utilized to move the moving body and a rotating body utilized to move the moving body. The drive force generation unit can be an engine, a motor, or the like. The rotating body can be a tire, a wheel, a screw propeller of the ship, a propeller of aircraft, or the like. In addition, the photoelectric conversion system 1908 can be applied not only to the moving body but also widely to equipment that utilizes object recognition such as an intelligent transportation system (ITS).

Although various types of equipment have been described according to the above-described embodiments, the mechanical apparatus may be further included. The mechanical apparatus in the camera can drive components of the optical system for zooming, focusing, and the operation of the shutter. The mechanical apparatus in the camera can move the photoelectric conversion apparatus for anti-vibration operation.

The equipment can be transport equipment such as a vehicle, a ship, aircraft, or the like. The mechanical apparatus in the transport equipment can be used as a moving apparatus. The equipment as the transport equipment can be equipment transporting the photoelectric conversion apparatus or equipment that, by using the image capturing function, assists and/or automates driving (piloting). The processing apparatus for assisting and/or automating the driving (piloting) can perform processing for operating the mechanical apparatus as the moving apparatus based on the information acquired by the photoelectric conversion apparatus.

### Ninth Embodiment

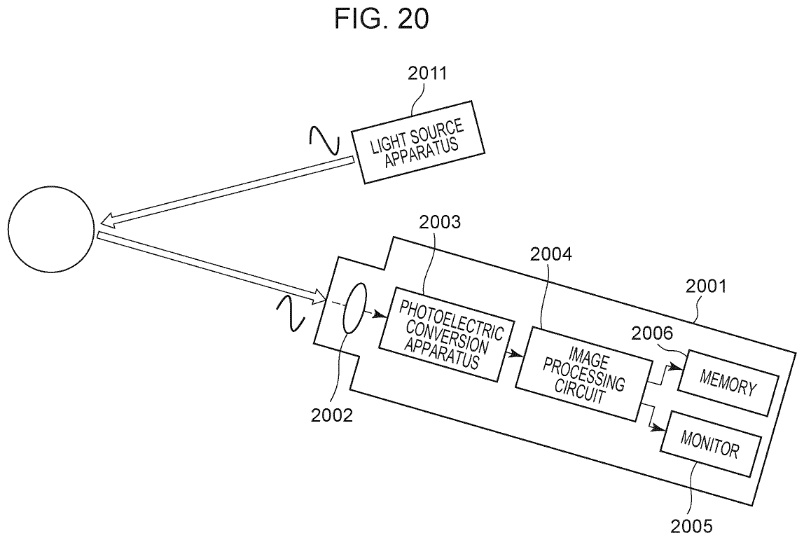

The photoelectric conversion system according to a ninth embodiment is described with reference to FIG. 20. FIG. 20 is a block diagram illustrating an example of the configuration of a distance image sensor being the photoelectric conversion system according to the present embodiment.

As illustrated in FIG. 20, a distance image sensor 2001 includes an optical system 2002, a photoelectric conversion apparatus 2003, an image processing circuit 2004, a monitor 2005, and memory 2006. The distance image sensor 2001 can acquire a distance image corresponding to the distance to an object by receiving light (modulation light or pulsed light) radiated from a light source apparatus 2011 toward the object and reflected by the surface of the object.

The optical system 2002 includes a single lens or a plurality of lenses. The optical system 2002 guides image light (incident light) from the object to the photoelectric conversion apparatus 2003 and causes the image light to form an image on a light-receiving surface (sensor unit) of the photoelectric conversion apparatus 2003.

The photoelectric conversion apparatus according to any one of the above-described embodiments is applied as the photoelectric conversion apparatus 2003. A distance signal indicating a distance acquired from a reception light signal output from the photoelectric conversion apparatus 2003 is supplied to the image processing circuit 2004.

The image processing circuit 2004 performs image processing to form the distance image based on the distance signal supplied from the photoelectric conversion apparatus 2003. The distance image (image data) acquired by the image processing is supplied to and displayed on the monitor 2005 or supplied to and stored (recorded) in the memory 2006.

The distance image sensor 2001 configured as described above can acquire, for example, a more exact distance image as the pixel characteristics improve when the above-described photoelectric conversion apparatus is applied.

### Tenth Embodiment

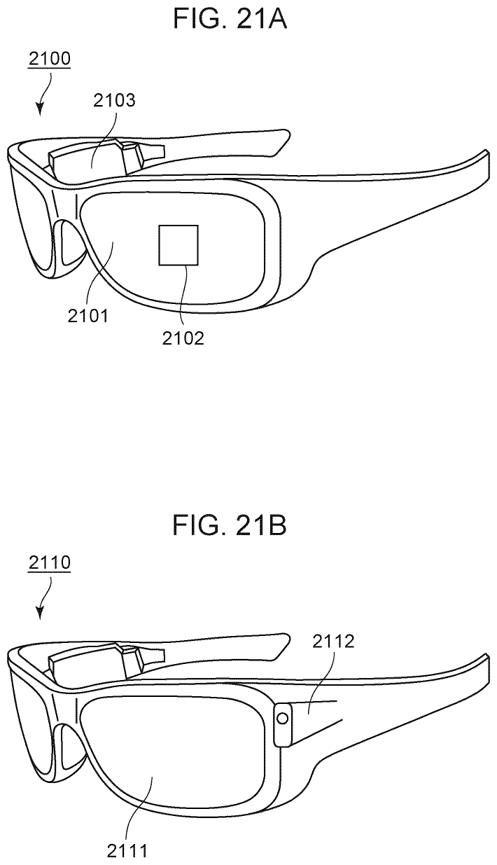

The photoelectric conversion system according to a tenth embodiment is described with reference to FIGS. 21A and 21B. FIG. 21A illustrates a pair of glasses 2100 (smart glasses) being the photoelectric conversion system according to the present embodiment. The pair of glasses 2100 include a photoelectric conversion apparatus 2102. The photoelectric conversion apparatus 2102 is the photoelectric conversion apparatus (image capturing apparatus) according to any one of the above-described embodiments. Furthermore, a display apparatus including a light emitting apparatus such as an organic light-emitting diode (OLED) or a light emitting diode (LED) may be provided on a rear surface side of a lens 2101. A single photoelectric conversion apparatus 2102 may be provided, or a plurality of photoelectric conversion apparatuses 2102 may be provided. Furthermore, a combination of a plurality of types of the photoelectric conversion apparatuses may be used. The position where the photoelectric conversion apparatus 2102 is disposed is not limited to the position illustrated in FIG. 21A.

The pair of glasses 2100 further includes a control apparatus 2103. The control apparatus 2103 functions as a power source that supplies power to the photoelectric conversion apparatus 2102 and the above-described display apparatus. Furthermore, the control apparatus 2103 controls operation of the photoelectric conversion apparatus 2102 and the display apparatus. An optical system for concentrating the light to the photoelectric conversion apparatus 2102 is formed in the lens 2101.

FIG. 21B illustrates a pair of glasses 2110 (smart glasses) according to an application example. The pair of glasses 2110 include a control apparatus 2112. A photoelectric conversion apparatus corresponding to the photoelectric conversion apparatus 2102 and a display apparatus are placed in the control apparatus 2112. An optical system for projecting the light emitted from the photoelectric conversion apparatus and the display apparatus in the control apparatus 2112 is formed in al lens 2111. Thus, an image is projected onto the lens 2111. The control apparatus 2112 functions as a power source that supplies power to the photoelectric conversion apparatus and the display apparatus. In addition, the control apparatus 2112 controls operation of the photoelectric conversion apparatus and the display apparatus. The control apparatus may include a line-of-sight detection unit configured to detect a line of sight of a wearer. Infrared radiation may be used for the detection of the line of sight. An infrared emitter emits infrared rays toward an eyeball of the user who gazes a displayed image. Reflected light of the emitted infrared rays from the eyeball is detected by an image capturing unit including a light receiving element. Thus, a captured image of the eyeball can be acquired. A reduction unit configured to reduce the light from the infrared emitter to a display unit in plan view is provided. Thus, degradation of the image is reduced.

The line of sight of the user to the displayed image is detected from the captured image of the eyeball obtained by capturing the infrared rays. Any known technique can be applied to the detection of the line of sight by using the captured image of the eyeball. As an example, a method for detecting a line of sight based on an Purkinje image due to reflection of light reflected at a cornea can be used.

More specifically, a line-of-sight detection process based on a pupil center corneal reflection method is performed. When a line-of-sight vector representing the direction of the eyeball (rotational angle) is calculated based on the Purkinje image and a pupil image included in the captured image of the eyeball by using the pupil center corneal reflection method, the line of sight of the user is detected.

The display apparatus according to the present embodiment may include the photoelectric conversion apparatus including the light receiving element and control a display image of the display apparatus based on the line-of-sight information of the user from the photoelectric conversion apparatus.

Specifically, for the display apparatus, a first sight region gazed by the user and a second sight region other than the first sight region are determined based on the line-of-sight information. The first sight region and the second sight region may be determined by the control apparatus of the display apparatus. Alternatively, the display apparatus may receive the first sight region and the second sight region determined by an external control apparatus. In a display region of the display apparatus, a display resolution of the first sight region may be controlled to be higher than a display resolution of the second sight region. That is, the resolution of the second sight region may be set to be lower than the resolution of the first sight region.

Furthermore, the display region may have a first display region and a second display region different from a first display region. Based on the line-of-sight information, a region to which a higher priority is given may be determined from the first display region and the second display region. The first sight region and the second sight region may be determined by the control apparatus of the display apparatus. Alternatively, the display apparatus may receive the first sight region and the second sight region determined by an external control apparatus. The resolution of the region of the higher priority may be controlled to be higher than the resolution of a region other than the region of the higher priority. That is, the resolution of a region of a relatively low priority may be reduced.

In determining the first sight region and the region of the high priority, artificial intelligence (AI) may be used. The AI may be a model configured to use, as training data, an image of the eyeball and the direction actually gazed by the eyeball of the image so as to estimate the angle of the line of sight and the distance to an object ahead of the line of sight from an image of the eyeball. An AI program may be included in the display apparatus, the photoelectric conversion apparatus, or the external apparatus. When the AI program is included in the external apparatus, the determination by the AI is transmitted to the display apparatus via communication.

When the display is controlled based on visually recognized detection, the AI can be applied to smart glasses that further include photoelectric conversion apparatus that captures external images. The smart glasses can display captured external information in real time.

### Eleventh Embodiment

The above-described photoelectric conversion apparatus may be applied to equipment, for example, electronic equipment such as a so-called smartphone or a tablet.

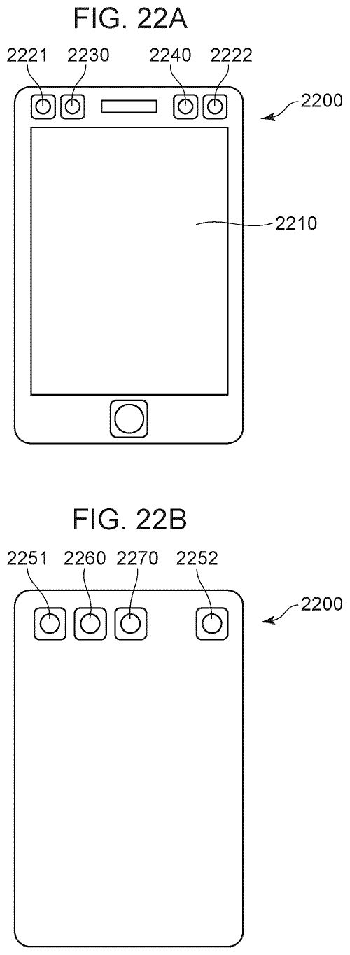

FIGS. 22A and 22B illustrate an example of electronic equipment 2200 in which the photoelectric conversion apparatus is placed. FIG. 22A illustrates a front surface side of the electronic equipment 2200, and FIG. 22B illustrates a rear surface side of the electronic equipment 2200.

As illustrated in FIG. 22A, a display 2210 configure to display images are disposed in the center of the front surface of the electronic equipment 2200. Along an upper side of the front surface of the electronic equipment 2200, front cameras 2221 and 2222 used by the photoelectric conversion apparatus, an infrared (IR) light source 2230 configured to emit infrared rays, and a visible light source 2240 configured to emit visible light are disposed.

Furthermore, as illustrated in FIG. 22B, along an upper side of the rear surface of the electronic equipment 2200, rear cameras 2251 and 2252 used by the photoelectric conversion apparatus, an IR light source 2260 configured to emit infrared rays, and a visible light source 2270 configured to emit visible light are disposed.

The electronic equipment 2200 configured as described above can capture, for example, images of higher grade when the above-described photoelectric conversion apparatus is applied. Other than the above description, the photoelectric conversion apparatus can be applied to electronic equipment such as an infrared sensor, a ranging sensor using an active infrared light source, a security camera, and a camera for personal authentication or biometrics authentication. Thus, accuracy, the performance, and the like of the above-described electronic equipment can be improved. Here, the types of the cameras and the light sources disposed on the front surface and the rear surface can be appropriately selected.

### Twelfth Embodiment

The above-described photoelectric conversion apparatus may be applied to a medical system such as an X-ray computerized tomography (CT) apparatus.

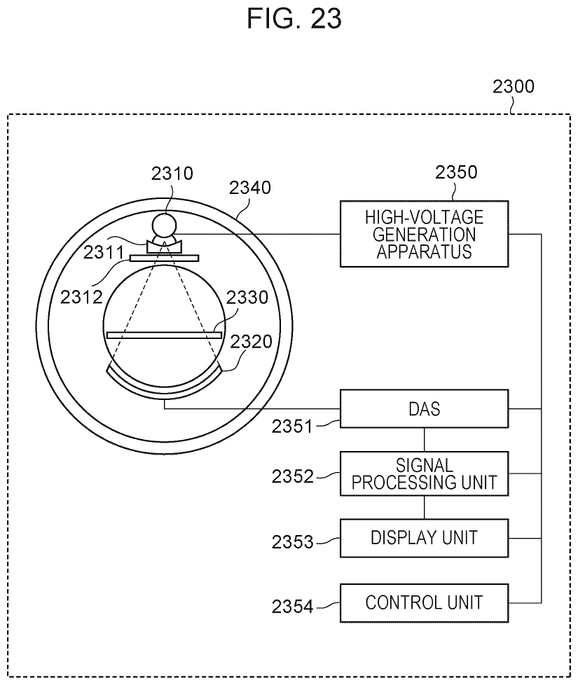

FIG. 23 is a block diagram of the X-ray CT apparatus according to a twelfth embodiment. The photoelectric conversion apparatus can be applied to a detector of the X-ray CT apparatus. An X-ray CT apparatus 2300 includes an X-ray generation unit 2310, a wedge 2311, a collimator 2312, an X-ray detection unit 2320, a top plate 2330, a rotating frame 2340, and a high-voltage generation apparatus 2350. The X-ray CT apparatus 2300 also includes a data acquisition system (DAS) 2351, a signal processing unit 2352, a display unit 2353, and a control unit 2354.

The X-ray generation unit 2310 includes, for example, a vacuum tube configured to generate X rays. A high voltage and a filament current are supplied from the high-voltage generation apparatus 2350 to the vacuum tube of the X-ray generation unit 2310. When thermions are radiated from a cathode (filament) to an anode (target), X rays are generated.

The wedge 2311 is a filter configured to adjust the amount of X rays radiated from the X-ray generation unit 2310. The wedge 2311 attenuates the amount of X rays so that the X rays radiated from the X-ray generation unit 2310 to an object to be studied are distributed in a predetermined manner. The collimator 2312 includes a lead plate or the like configured to narrow down a radiation range of the X-rays having transmitted through the wedge 2311. The X rays generated by the X-ray generation unit 2310 are formed into a cone beam shape via the collimator 2312 and radiated to the object to be studied on the top plate 2330.

The X-ray detection unit 2320 includes the above-described photoelectric conversion apparatus. The X-ray detection unit 2320 is configured to detect the X rays having passed from the X-ray generation unit 2310 through the object to be studied and output a signal corresponding to the amount of X rays to the DAS 2351.

The rotating frame 2340 has an annular shape and configured so as to be rotatable. The X-ray generation unit 2310 (the wedge 2311 and the collimator 2312) and the X-ray detection unit 2320 are disposed in the rotating frame 2340 so as to face each other. The X-ray generation unit 2310 and the X-ray detection unit 2320 are rotatable together with the rotating frame 2340.

The high-voltage generation apparatus 2350 includes a boosting circuit and is configured to output a high voltage to the X-ray generation unit 2310. The DAS 2351 includes a amplifier circuit and an analog-to-digital conversion circuit and is configured to output a signal from the X-ray detection unit 2320 to the signal processing unit 2352 as digital data.

The signal processing unit 2352 includes a CPU, read only memory (ROM), and random-access memory (RAM). The signal processing unit 2352 can execute image processing or the like of the digital data. The display unit 2353 includes a flat display apparatus or the like. The display unit 2353 can display an X-ray image. The control unit 2354 includes a CPU, ROM, RAM, and the like. The control unit 2354 is configured to control operation of the entirety of the X-ray CT apparatus 2300.

Although, according to the above-described embodiments, the description has been made based on the form of the lamination sensor in which the sensor substrate 11 and the circuit substrate 21 are laminated, this example is not limiting. That is, all the members illustrated in FIG. 3 may be disposed in a single chip.

Herein, expressions such as “A or B”, “at least one of A and B”, “at least one of A and/or B”, and “one or more of A and/or B” can include all the possible combinations of listed items unless otherwise explicitly defined.

That is, the above-described expressions are to be understood that the above-described expressions disclose all the following cases: a case where at least one A is included; a case where at least one B is included; and a case where both the at least one A and the at least one B are included. This is to be applied similarly or in the same manner to combinations of three or more elements.

The embodiments having been described can be changed as appropriate without departing from the technical thought. The content of the disclosure herein includes not only the explicit description herein but also all the items understandable herein and from the attached drawings. The content of the disclosure herein includes complements of individual concepts described herein. That is, when, for example, description indicating to the effect that “A is greater than B” is included herein, this can mean that a description indicating to the effect that “A is not greater than B” is also disclosed herein even when the description indicating to the effect that “A is not greater than B” is omitted. The reason for this is that, when the description indicating to the effect that “A is greater than B” is included, this description is made on the assumption that the case of “A is not greater than B” is considered.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-057460 filed Mar. 29, 2024, which is hereby incorporated by reference herein in its entirety.

What is claimed is:

1. A photoelectric conversion apparatus comprising:
a semiconductor layer having a first surface and a second surface facing the first surface;
a first photoelectric conversion element disposed in the semiconductor layer;
a second photoelectric conversion element disposed in the semiconductor layer;
an uneven portion disposed in the second surface of the semiconductor layer so as to correspond to the first photoelectric conversion element, the uneven portion having a groove of the semiconductor layer;
an isolation portion disposed between the first photoelectric conversion element and the second photoelectric conversion element, the isolation portion having a groove of the semiconductor layer;
a first film disposed in at least part of the groove of the uneven portion on a second surface side; and
a second film disposed in at least part of the groove of the isolation portion,
wherein the groove of the isolation portion extends through the first film into the semiconductor layer, and
wherein the second film extends from a side surface of the groove of the isolation portion on the first film.

2. The photoelectric conversion apparatus according to claim 1,
wherein the first film includes
a first layer formed of a material selected from the group consisting of aluminum oxide, hafnium oxide, zirconium oxide, and tantalum oxide,
a second layer formed of a material selected from the group consisting of aluminum oxide, hafnium oxide, zirconium oxide, and tantalum oxide, and
a third layer formed of a material selected from the group consisting of silicon oxide and silicon oxynitride.

3. The photoelectric conversion apparatus according to claim 1,
wherein a width of the groove of the isolation portion is greater than or equal to twice a width of the groove of the uneven portion and smaller than or equal to ten times the width of the groove of the uneven portion.

4. The photoelectric conversion apparatus according to claim 1,
wherein the isolation portion further includes a light shielding member.

5. The photoelectric conversion apparatus according to claim 4,
wherein the light shielding member is a conductor film.

6. A photoelectric conversion system comprising:
the photoelectric conversion apparatus according to claim 1; and
a signal processing unit configured to generate an image by using a signal output by the photoelectric conversion apparatus.

7. A moving body comprising:
the photoelectric conversion apparatus according to claim 1; and
a control unit configured to control a movement of the moving body by using a signal output by the photoelectric conversion apparatus.

8. Equipment comprising:
the photoelectric conversion apparatus according to claim 1; and
at least one apparatus selected from the group consisting of:
an optical apparatus corresponding to the photoelectric conversion apparatus,
a control apparatus configured to control the photoelectric conversion apparatus,
a processing apparatus configured to process a signal output from the photoelectric conversion apparatus,
a display apparatus configured to display information acquired by the photoelectric conversion apparatus,
a storage apparatus configured to store the information acquired by the photoelectric conversion apparatus, and
a mechanical apparatus configured to operate based on the information acquired by the photoelectric conversion apparatus.

9. A method for manufacturing a photoelectric conversion apparatus, the method comprising:
preparing a semiconductor layer having a first surface and a second surface facing the first surface, a first photoelectric conversion element and a second photoelectric conversion element being disposed in the semiconductor layer;
forming a first groove by etching at a first position corresponding to a second position on a second surface side of the semiconductor layer, the first photoelectric conversion element of the semiconductor layer being disposed at the second position;
forming a first film in the first groove;
forming a second groove by etching at a third position corresponding to a fourth position on the second surface side of the semiconductor layer between the first photoelectric conversion element and the second photoelectric conversion element of the semiconductor layer;
forming an opening in the first film in the forming of the second groove; and
forming a second film so as to extend from a side surface of the second groove to cover an upper side of the first film.

10. The method according to claim 9,
wherein a width of the second groove is greater than or equal to twice a width of the first groove and smaller than or equal to ten times the width of the first groove.

11. The method according to claim 9, further comprising:
performing isotropic etching on the first groove after the forming of the first groove.

12. The method according to claim 11, further comprising:
performing isotropic etching on the second groove after the forming of the second groove.
